(19) United States
(12) Patent Application Publication
(10) Pub. No.: US 2024/0182644 A1
(43) Pub. Date: Jun. 6, 2024

(54) CURABLE RESIN COMPOSITION AND CURED OBJECT OBTAINED THEREFROM

(71) Applicant: NIPPON KAYAKU KABUSHIKI KAISHA, Tokyo (JP)

(72) Inventors: Takafumi MIZUGUCHI, Tokyo (JP); Mao TAKEDA, Tokyo (JP); Kazuyoshi YAMAMOTO, Tokyo (JP); Kengo NISHIMURA, Tokyo (JP)

(73) Assignee: NIPPON KAYAKU KABUSHIKI KAISHA, Tokyo (JP)

(21) Appl. No.: 18/284,102

(22) PCT Filed: Mar. 25, 2022
(86) PCT No.: PCT/JP2022/014726

§ 371 Date: Sep. 26, 2023

(30) Foreign Application Priority Data
Mar. 30, 2021 (JP) 2021-056835

(51) Int. Cl. C08G 73/10; C08G 61/10; C08L 77/06

(52) U.S. Cl. CPC C08G 73/10; C08G 61/10; C08L 77/06; C08L 2203/16; C08L 2203/20

(57) ABSTRACT

A curable resin composition containing:
a maleimide resin (A) having a cyclic imide bond obtained by reacting a diamine (a-1) derived from a dimer acid, a tetracarboxylic dianhydride (a-2), and a maleic anhydride;
a maleimide resin (B) represented by the following formula (1); and
a curing accelerator (D), in which

the components (A), (B), and (D) are compatible with one another:

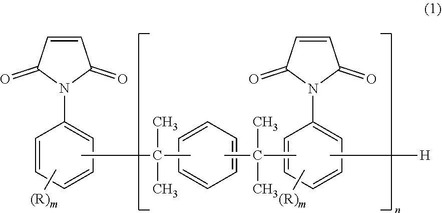

in the formula (1), plural R each independently represent a hydrogen atom or an alkyl group having 1 to 5 carbon atoms. m represents an integer of 0 to 3. n represents the number of repetitions, and an average value thereof is 1<n<5.

### TECHNICAL FIELD

The present invention relates to a curable resin composition and a cured object obtained therefrom.

The curable resin composition according to the present invention can be applied to a protective film, an interlayer insulating film, an insulating film of a redistribution layer, an underfill, and the like which can be used for a semiconductor device, a semiconductor substrate, and the like.

### BACKGROUND ART

In recent years, required properties of a laminate on which an electric/electronic component is mounted have been extensive and sophisticated with the expansion of the field of use thereof. For example, in the related art, a semiconductor chip is mainly mounted on a metal lead frame, but a semiconductor chip having a high processing capability such as CPU is often mounted on a laminate made of a polymer material. As a speed of an element such as CPU increases and a clock frequency increases, signal propagation delay and transmission loss become problems, and a wiring board is required to have a low permittivity and a low loss tangent. At the same time, as the speed of the device increases, the heat generation of the chip increases, and thus it is necessary to increase the heat resistance. In addition, in recent years, mobile electronic devices such as mobile phones have been widely used, and precision electronic devices have been used and carried in an outdoor environment or in the vicinity of a human body, and thus the resistance to an external environment (in particular, moisture and heat resistance environment) is required. Further, in the field of automatic vehicles, digitization rapidly progresses, a precision electronic device may be disposed near an engine, and a higher level of heat resistance and moisture resistance is required.

A wiring board using a BT resin, which is a resin in which a bisphenol A-type cyanate ester compound and a bismaleimide compound are used in combination, as disclosed in Patent Literature 1 is excellent in heat resistance, chemical resistance, electrical properties, and the like, and is widely used as a high-performance wiring board in the related art. However, an improvement is required under a situation in which high performance is required as described above.

In such a situation, a commercially available maleimide compound is often a low molecular weight and rigid bismaleimide compound, and needs to be used in the form of a solution because it is a crystal having a high melting point. However, the maleimide compound has a disadvantage of being difficult to dissolve in a general-purpose organic solvent, and being dissolved only in a solvent having a high boiling point and a high hygroscopicity such as N,N-dimethylacetamide and N-methyl-2-pyrrolidone. In addition, a cured object of the bismaleimide compound has good heat resistance, but has a disadvantage of being brittle and having high hygroscopicity.

On the other hand, maleimide resins, as in Patent Literatures 2 and 3, having a molecular weight distribution, a relatively low softening point, and good solvent solubility as compared with a bismaleimide compound in the related art have been developed. However, since there is a problem in adhesion to a base material under a high temperature environment, in particular, adhesion to a material such as silicon or copper used as a material of a device or a substrate at a high temperature, the adhesiveness is not yet sufficient.

### CITATION LIST

### Patent Literature

Patent Literature 1: JPS54-30440B

Patent Literature 2: JPH03-100016A

Patent Literature 3: Japanese Patent No. 5030297

Patent Literature 4: Japanese Patent No. 6689475

Patent Literature 5: JPH04-75222B

Patent Literature 6: Japanese Patent No. 6752390

### SUMMARY OF INVENTION

### Technical Problem

In general, in a case of an attempt to improve Tg of a resin composition for the purpose of improving the heat resistance, a resin having a ring structure is often used. In this case, the solubility in a solvent tends to decrease as the number of ring structures in a molecule increases. In addition, the compatibility between the resins is also reduced. Even maleimide resins are not necessarily compatible with each other. In particular, combinations of resins having plural long-chain aliphatic chains and ring structures are generally incompatible with each other. A cured object composed of a resin composition using resins that are not compatible with each other is inferior in heat resistance and causes cracking. Thus the cured object is unsuitable for use in applications such as a protective film, an interlayer insulating film, an insulating film of a redistribution layer, and underfill that are used for a semiconductor device, a semiconductor substrate, and the like.

The present invention has been made in view of such circumstances and relates to a resin composition containing maleimide resins that are compatible with each other even when main skeletons are different from each other, and an object thereof is to provide a curable resin composition and a cured object thereof that exhibit excellent heat resistance, mechanical properties, and low dielectric properties.

By using two or more types of maleimide resins that are compatible with each other even when the main skeletons are different from each other, it is possible to obtain a cured object having excellent mechanical properties and low dielectric properties while taking advantage of merits based on respective mother skeletons, that is, flexibility due to a long chain skeleton and high heat resistance due to plural ring structures.

Further, the resin composition that is stable and has excellent compatibility even in a solution state can improve workability at the time of producing the resin composition, and can expand a range of material design because other various materials can be mixed.

### Solution To Problem

As a result of intensive studies to solve the above problems, the present inventors have completed the present invention. That is, the present invention relates to the following [1] to [15].

[1]

A curable resin composition containing:
a maleimide resin (A) having a cyclic imide bond obtained by reacting a diamine (a-1) derived from a dimer acid, a tetracarboxylic dianhydride (a-2), and a maleic anhydride;
a maleimide resin (B) represented by the following formula (1); and
a curing accelerator (D), in which
the components (A), (B), and (D) are compatible with one another.

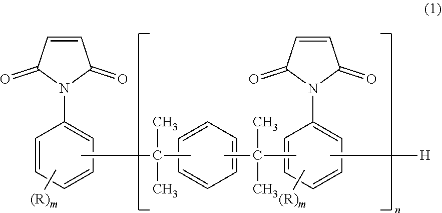

(In the formula (1), plural R each independently represent a hydrogen atom or an alkyl group having 1 to 5 carbon atoms. m represents an integer of 0 to 3. n is the number of repetitions, and an average value thereof is 1<n<5.)

[2]

The curable resin composition according to [1], in which
the component (A) is represented by the following formula (2).

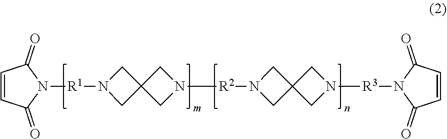

(In the formula (2),
R¹ represents a divalent hydrocarbon group (a) derived from a dimer acid,
R² represents a divalent organic group (b) other than the divalent hydrocarbon group (a) derived from a dimer acid,
R³ represents any one selected from the group consisting of:
   the divalent hydrocarbon group (a) derived from a dimer acid; and
   the divalent organic group (b) other than the divalent hydrocarbon group (a) derived from a dimer acid, and
R⁴ and R⁵ each independently contain one or more organic groups selected from:
   a tetravalent organic group having 6 to 40 carbon atoms and having a monocyclic or condensed polycyclic alicyclic structure;
   a tetravalent organic group having 4 to 40 carbon atoms in which organic groups having a monocyclic alicyclic structure are linked to one another directly or via a crosslinked structure; and
   a tetravalent organic group having 4 to 40 carbon atoms and having a semi-alicyclic structure including both an alicyclic structure and an aromatic ring,
   in an amount of 5 mol % to 95 mol % when a total amount of R⁴ and R⁵ is 100 mol %. m is an integer of 1 to 30, n is an integer of 0 to 30, in a case where m is 2 or more, plural R¹ and R⁴ may be the same or different, and in a case where n is 2 or more, plural R² and R⁵ may be the same or different.)
      [3]

The curable resin composition according to [1] or [2], in which
the component (a-2) is represented by the following formula (3-a).

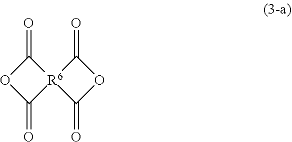

(In the formula (3-a), R⁶ represents a tetravalent organic group having 4 to 40 carbon atoms including a hydrocarbon ring, and the organic group may contain an aromatic ring.)

[4]

The curable resin composition according to [3], in which the component (a-2) is selected from the group consisting of the following formulae (4-1a) to (4-11a).

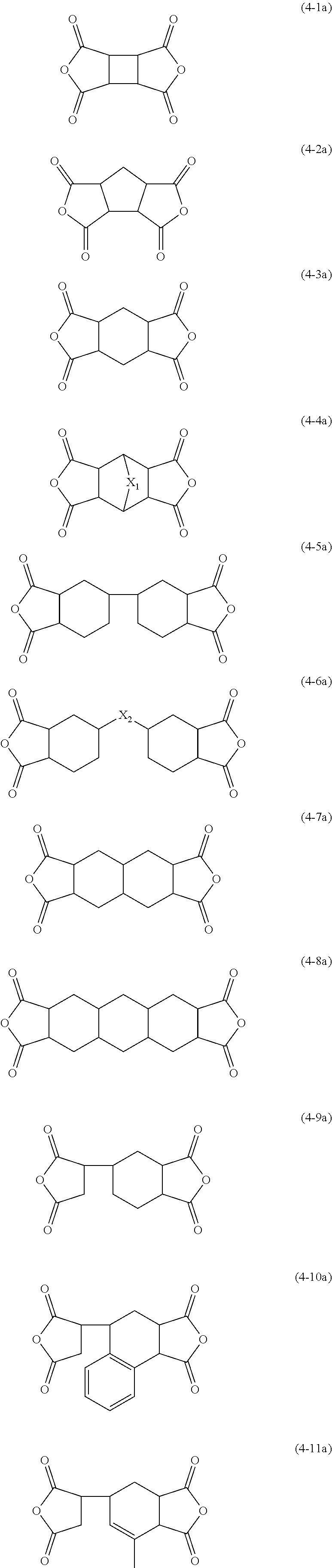

(In the formula (4-4a), X₁ represents a direct bond, an oxygen atom, a sulfur atom, a sulfonyl group, or a divalent organic group having 1 to 3 carbon atoms. In the formula (4-6a), X₂ represents a direct bond, an oxygen atom, a sulfur atom, a sulfonyl group, or a divalent organic group having 1 to 3 carbon atoms or arylene group.)

[5]

The curable resin composition according to any one of [1] to [4], further containing:
a thermosetting resin (C) other than the component (A) and the component (B), in which
the components (A) to (D) are compatible with one another.

[6]

The curable resin composition according to [5], in which
the component (C) is one or more selected from the group consisting of: a maleimide compound other than the component (A) and the component (B), a cyanate ester compound, a phenolic resin, an epoxy resin, an oxetane resin, a benzoxazine compound, a carbodiimide compound, and a compound containing an ethylenically unsaturated group.
   [7]

The curable resin composition according to [5] or [6], in which the component (C) is a compound represented by the following formula (5).

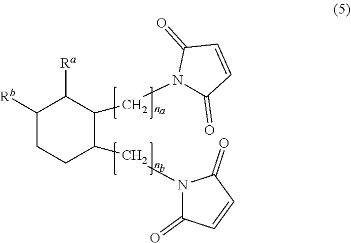

(In the formula (5), R^{a} and R^{b} each independently represents a linear or branched alkyl group having 1 to 16 carbon atoms, or a linear or branched alkenyl group having 1 to 16 carbon atoms. na represents the number of 1 to 16, and nb represents the number of 1 to 16. na and nb may be the same or different.)

[8]

The curable resin composition according to any one of [1] to [7], in which
the component (a-2) is a compound represented by the following formula (6).

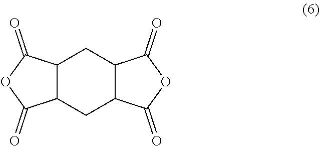 [SMILES: O=C1OC(=O)C2CC3C(=O)OC(=O)C3CC12]

[9]

The curable resin composition according to any one of [1] to [7], in which
the component (a-2) is a compound represented by the following formula (7).

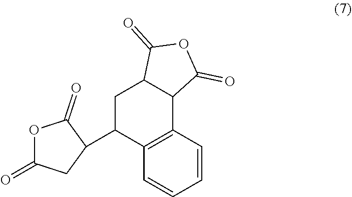 [SMILES: O=C1CC(C2CC3C(=O)OC(=O)C3c3ccccc32)C(=O)O1]

[10]

The curable resin composition according to any one of [1] to [9], in which the component (D) contains at least one selected from a thermal radical polymerization initiator and an imidazole compound.

[11]

The curable resin composition according to [10], in which
the thermal radical polymerization initiator is an organic peroxide.
   [12]

The curable resin composition according to any one of [1] to [11], in which
a content of the component (A) is 30 wt % or more and less than 95 wt %, a content of the component (B) is 3 wt % or more and less than 60 wt % in a total amount of the curable resin composition, and
the content of the component (A) is larger than the content of the component (B).
   [13]

The curable resin composition according to any one of [1] to [12], having a haze value of less than 50 that is measured at an optical path length of 10 mm in accordance with JIS K7136.

[14]

A resin sheet containing the curable resin composition according to any one of [1] to [13].

[15]

A cured object obtained by curing the curable resin composition according to any one of [1] to [13].

[16]

A semiconductor device and a semiconductor substrate including the cured object according to claim 15 as at least one selected from the group consisting of a surface protective film, an interlayer insulating film, an insulating film of a redistribution layer, and an underfill.

### Advantageous Effects Of Invention

The curable resin composition according to the present invention is excellent in solution stability and compatibility, the workability is greatly improved, and the cured object thereof is excellent in mechanical properties and low dielectric properties.

### DESCRIPTION OF EMBODIMENTS

Hereinafter, the present invention will be described in detail.

First, a method for producing a maleimide resin according to the present invention will be described.

A maleimide resin (A) according to the present invention contains a divalent hydrocarbon group (a) derived from a dimer acid and a cyclic imide bond. Such a maleimide resin (A) can be obtained by reacting: a diamine (a-1) derived from the dimer acid; a tetracarboxylic dianhydride (a-2); and a maleic anhydride.

The divalent hydrocarbon group (a) derived from the dimer acid refers to a divalent residue obtained by removing two carboxyl groups from a dicarboxylic acid contained in the dimer acid. In the present invention, such a divalent hydrocarbon group (a) derived from a dimer acid can be introduced into a maleimide resin by reacting: a diamine (a-1) obtained by substituting two carboxyl groups of the dicarboxylic acid contained in the dimer acid with amino groups; the tetracarboxylic dianhydride (a-2); and the maleic anhydride to be described later to form an imide bond.

In the present invention, the dimer acid is preferably a dicarboxylic acid having 20 to 60 carbon atoms. Specific examples of the dimer acid include those obtained by dimerizing unsaturated bonds of unsaturated carboxylic acids such as linoleic acid, oleic acid, and linolenic acid, followed by distillation and purification. The dimer acid of the specific example mainly contains a dicarboxylic acid having 36 carbon atoms, and generally contains a tricarboxylic acid having 54 carbon atoms and a monocarboxylic acid each at a limit of about 5 mass %. The diamine (a-1) derived from the dimer acid according to the present invention (hereinafter, referred to as “dimer acid-derived diamine (a-1)” in some cases) is a diamine obtained by substituting two carboxyl groups of each dicarboxylic acid contained in the dimer acid with an amino group, and is generally a mixture. In the present invention, examples of such a dimer acid-derived diamine (a-1) include a diamine such as [3,4-bis(1-aminoheptyl)6-hexyl-5-(1-octenyl)]cyclohexane and a diamine in which unsaturated bonds are saturated by further hydrogenation to the diamine.

The divalent hydrocarbon group (a) derived from the dimer acid according to the present invention, which is introduced into a maleimide resin using such a diamine (a-1) to derived from the dimer acid, is preferably a residue obtained by removing two amino groups from the diamine (a-1) derived from a dimer acid. In addition, when the maleimide resin (A) according to the present invention is obtained using the diamine (a-1) derived from the dimer acid, the diamine (a-1) derived from the dimer acid may be used alone or in combination of two or more types having different compositions. Further, as such a diamine (a-1) derived from the dimer acid, for example, a commercially available product such as “PRIAMINE 1074” (manufactured by Croda Japan K.K.) may be used.

In the present invention, the tetracarboxylic dianhydride (a-2) is a tetracarboxylic dianhydride having an alicyclic structure adjacent to an anhydride group. The tetracarboxylic dianhydride (a-2) has a structure in which an imide ring adjacent site becomes an alicyclic structure when a bismaleimide compound is obtained after the reaction. As long as the imide ring adjacent site becomes an alicyclic structure, the structure may further contain an aromatic ring. In the present invention, the maleimide resin (A) is preferably represented by the following formula (2). In the formula (2), R⁴ and R⁵ are structures derived from the tetracarboxylic dianhydride (a-2).

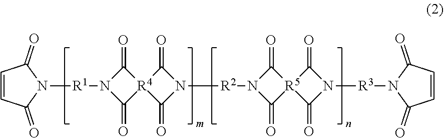

(In the formula (2),
R¹ represents the divalent hydrocarbon group (a) derived from a dimer acid,
R² represents a divalent organic group (b) other than the divalent hydrocarbon group (a) derived from a dimer acid,
R³ represents any one selected from the group including the divalent hydrocarbon group (a) derived from a dimer acid and the divalent organic group (b) other than the divalent hydrocarbon group (a) derived from a dimer acid, and
R⁴ and R⁵ each independently represent one or more organic groups selected from: a tetravalent organic group having 4 to 40 carbon atoms (preferably 6 to 40 carbon atoms) and to having a monocyclic or condensed polycyclic alicyclic structure;
a tetravalent organic group having 8 to 40 carbon atoms in which organic groups having a monocyclic alicyclic structure are linked to one another directly or via a crosslinked structure; and
a tetravalent organic group having 8 to 40 carbon atoms and having a semi-alicyclic structure including both an alicyclic structure and an aromatic ring. m is an integer of 1 to 30, n is an integer of 0 to 30, and R⁴ and R⁵ may be the same or different.)

In the present invention, the tetracarboxylic dianhydride (a-2) preferably has an alicyclic structure represented by the following formula (3). The tetracarboxylic dianhydride (a-2) including the alicyclic structure represented by the following formula (3) has an alicyclic structure adjacent to an anhydride group.

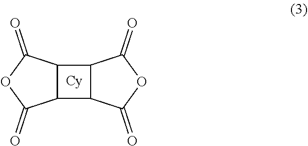 [SMILES: O=C1OC(=O)C2C1C1C(=O)OC(=O)C21]

(In the formula (3), Cy is a tetravalent organic group having 4 to 40 carbon atoms and containing a hydrocarbon ring, and the organic group may contain an aromatic ring.)

The tetracarboxylic dianhydride (a-2) having the alicyclic structure represented by the formula (3) can be specifically represented by the following formula (3-a).

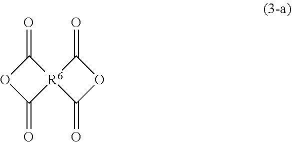

(In the formula (3-a), R⁶ represents a tetravalent organic group having 4 to 40 carbon atoms including a hydrocarbon ring, and the organic group may contain an aromatic ring.)

In the present invention, the tetracarboxylic dianhydride (a-2) preferably has an alicyclic structure represented by the following formulae (4-1) to (4-11). The tetracarboxylic dianhydride (a-2) represented by the formulae (4-1) to (4-11) has a structure containing: a tetravalent organic group having 4 to 40 carbon atoms (preferably 6 to 40 carbon atoms) and having a monocyclic or condensed polycyclic alicyclic structure; a tetravalent organic group having 8 to 40 carbon atoms in which organic groups each having a monocyclic alicyclic structure are linked to one another directly or via a crosslinked structure; or a tetravalent organic group having 8 to 40 carbon atoms and having a semi-alicyclic structure including both an alicyclic structure and an aromatic ring.

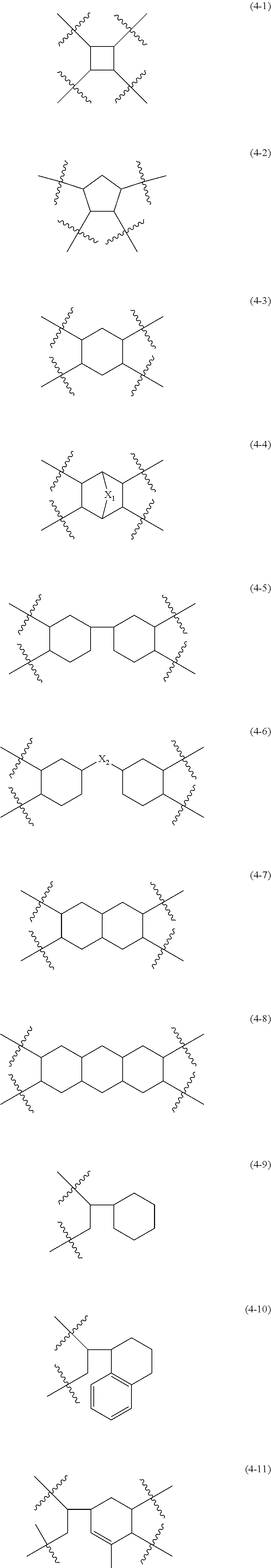

(In the formula (4-4), X₁ represents a direct bond, an oxygen atom, a sulfur atom, a sulfonyl group, or a divalent organic group having 1 to 3 carbon atoms. In the formula (4-6), X₂ represents a direct bond, an oxygen atom, a sulfur atom, a sulfonyl group, or a divalent organic group having 1 to 3 carbon atoms or arylene group.)

The tetracarboxylic dianhydride (a-2) having an alicyclic structure represented by the formulae (4-1) to (4-11) can be specifically represented by the following formulae (4-a) to (4-11a).

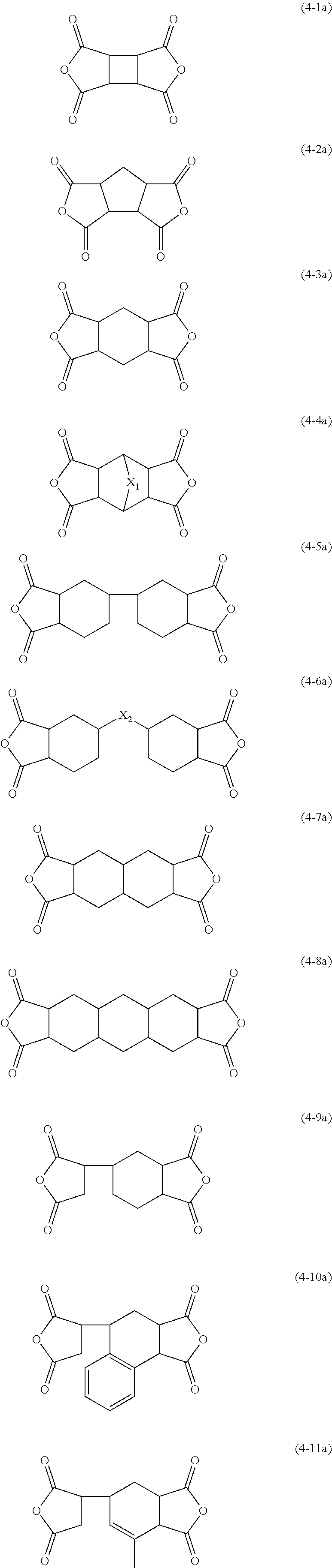

(In the formula (4-4a), X₁ represents a direct bond, an oxygen atom, a sulfur atom, a sulfonyl group, or a divalent organic group having 1 to 3 carbon atoms. In the formula (4-6a), X₂ represents a direct bond, an oxygen atom, a sulfur atom, a sulfonyl group, or a divalent organic group having 1 to 3 carbon atoms or arylene group.)

The tetracarboxylic dianhydride (a-2) used in the present invention contains: a tetravalent organic group having 4 to 40 carbon atoms (preferably 6 to 40 carbon atoms) and having a monocyclic or condensed polycyclic alicyclic structure; a tetravalent organic group having 8 to 40 carbon atoms in which organic groups each having a monocyclic alicyclic structure are linked to one another directly or via a crosslinked structure; or a tetravalent organic group having 8 to 40 carbon atoms and having a semi-alicyclic structure including both an alicyclic structure and an aromatic ring. Specific examples of the tetracarboxylic dianhydride (a-2) having an alicyclic structure include: an alicyclic tetracarboxylic dianhydride such as 1,2,3,4-cyclobutanetetracarboxylic dianhydride (CBDA), 1,2-dimethyl-1,2,3,4-cyclobutanetetracarboxylic dianhydride, 1,2,3,4-tetramethyl-1,2,3,4-cyclobutanetetracarboxylic dianhydride, 1,2,3,4-cyclopentanetetracarboxylic dianhydride, 1,2,4,5-cyclohexanetetracarboxylic dianhydride (H-PMDA), 1,1′-bicyclohexane-3,3′,4,4′-tetracarboxylic acid-3,4:3′,4′-dianhydride (H-BPDA), 4-(2,5-dioxotetrahydrofuran-3-yl)-1,2,3,4-tetrahydronaphthalene-1,2-dicarboxylic anhydride, 5-(2,5-dioxotetrahydrofuryl)-3-methyl-3-cyclohexene-1,2-dicarboxylic anhydride, bicyclo[2.2.2]oct-7-ene-2,3,5,6-tetracarboxylic dianhydride, 2,3,4,5-tetrahydrofurantetracarboxylic dianhydride, or 3,5,6-tricarboxy-2-norbornane acetic dianhydride; a compound obtained by substituting an aromatic ring thereof with an alkyl group or a halogen atom; a semi-alicyclic tetracarboxylic dianhydride such as 1,3,3a,4,5,9b-hexahydro-5(tetrahydro-2,5-dioxo-3-furanyl)naphtho[1,2-c]furan-1,3-dione; or a compound obtained by substituting a hydrogen atom of an aromatic ring thereof with an alkyl group or a halogen atom.

In the present invention, the tetracarboxylic dianhydride (a-2) preferably has an alicyclic structure represented by the following formula (6).

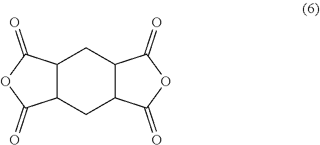 [SMILES: O=C1OC(=O)C2CC3C(=O)OC(=O)C3CC12]

In the present invention, the tetracarboxylic dianhydride (a-2) preferably has an alicyclic structure represented by the following formula (7).

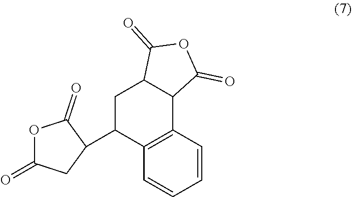 [SMILES: O=C1CC(C2CC3C(=O)OC(=O)C3c3ccccc32)C(=O)O1]

In the present invention, in addition to the tetracarboxylic dianhydride (a-2) having an alicyclic structure, a dianhydride having no alicyclic structure or a dianhydride containing an aromatic ring adjacent to an anhydride group may be added. In a total amount of the dianhydrides, a lower limit of the tetracarboxylic dianhydride (a-2) is preferably 40 mol % or more, more preferably 80 mol % or more, and particularly preferably 90 mol % or more. An upper limit may be 100 mol % or less. In a case where the content of the tetracarboxylic dianhydride (a-2) in the total amount of the dianhydrides is less than 40 mol %, the light gathering rate is low and a small pattern opening tends not to be obtained, and thus a resolution of the obtained pattern may decrease.

Specific examples of the dianhydride containing an aromatic ring adjacent to an anhydride group other than the tetracarboxylic dianhydride (a-2) include: aromatic tetracarboxylic dianhydrides such as pyromellitic dianhydride, 4,4′-oxydiphthalic dianhydride, 3,3′,4,4′-biphenyltetracarboxylic dianhydride, 2,3,3′,4′-biphenyltetracarboxylic dianhydride, 2,2′,3,3′-biphenyltetracarboxylic dianhydride, 3,3′,4,4′-benzophenonetetracarboxylic dianhydride, 2,2′,3,3′-benzophenonetetracarboxylic dianhydride, 2,2-bis(3,4-dicarboxyphenyl)propane dianhydride, 2,2-bis(2,3-dicarboxyphenyl)propane dianhydride, 1,1-bis(3,4-di carboxyphenypethane dianhydride, 1,1-bis(2,3-dicarboxyphenypethane dianhydride, bis(3,4-dicarboxyphenyl)methane dianhydride, bis(2,3-dicarboxyphenyl)methane dianhydride, 1,2,5,6-naphthalenetetracarboxylic dianhydride, 2,3,6,7-naphthalenetetracarboxylic dianhydride, 2,3,5,6-pyridinetetracarboxylic dianhydride, and aromatic acid dianhydrides such as: 3,4,9,10-perylenetetracarboxylic dianhydride; bis(3,4-dicarboxyphenyl)sulfone dianhydride, bis(3,4-dicarboxyphenyl)ether dianhydride, 2,2-bis(3,4-dicarboxyphenyl)hexafluoropropane dianhydride, or a compound obtained by substituting an aromatic ring of these compounds with an alkyl group or a halogen atom, and dianhydride containing an amide group. These may be used in combination with two or more types of dianhydrides having 4 to 40 carbon atoms and having an alicyclic structure or a semi-alicyclic structure.

Further, the maleimide resin (A) may be a bismaleimide compound obtained by reacting: the dimer acid-derived diamine (a-1); an organic diamine (a-3) other than the dimer acid-derived diamine (a-1); the tetracarboxylic dianhydride (a-2); and the maleic anhydride. By copolymerizing the organic diamine (a-3) other than the dimer acid-derived diamine (a-1), it is possible to control the required physical properties as necessary such as further lowering a tensile elastic modulus of the obtained cured object.

In the present invention, the organic diamine (a-3) other than the diamine (a-1) derived from the dimer acid (hereinafter, simply referred to as “an organic diamine (a-3)” in some cases) refers to a diamine other than the diamine contained in the diamine (a-1) derived from the dimer acid. Such an organic diamine (a-3) is not particularly limited, and examples thereof include: aliphatic diamines such as 1,6-hexamethylene diamine; alicyclic diamines such as 1,4-diaminocyclohexane and 1,3-bis(amino methyl)cyclohexane; aromatic diamines such as 4,4′-diaminodiphenyl ether, 3,4′-diaminodiphenyl ether, 1,4-bis(4-aminophenoxy) benzene, 1,3-bis(aminomethyl)benzene, 1,3-bis(4-aminophenoxy)benzene, 1,3-bis(3-aminophenoxy) benzene, 1,4-diaminobenzene, 1,3-diaminobenzene, 2,4-diaminotoluene, and 4,4′-diaminodiphenylmethane; 4,4′-diaminodiphenyl sulfone; 3,3′-diaminodiphenyl sulfone; 4,4′-diaminobenzophenone; 4,4′-diaminodiphenyl sulfide; and 2,2-bis[4-(4-aminophenoxy)phenyl]propane. Among them, from the viewpoint of obtaining a cured object having a lower tensile elastic modulus, an aliphatic diamine having 6 to 12 carbon atoms such as 1,6-hexamethylene diamine; diaminocyclohexane such as 1,4-diaminocyclohexane; and an aromatic diamine having an aliphatic structure having 1 to 4 carbon atoms in an aromatic skeleton such as 2,2-bis[4-(4-aminophenoxy)phenyl]propane are more preferable. In addition, when the maleimide resin (A) according to the present invention is obtained by using these organic diamines (a-3), these organic diamines (a-3) may be used alone or in combination with two or more types thereof.

A method of reacting: the diamine (a-1) derived from the dimer acid; the tetracarboxylic dianhydride (a-2) having an alicyclic structure; and the maleic anhydride, or a method of reacting: the diamine (a-1) derived from the dimer acid; the organic diamine (a-3); the tetracarboxylic dianhydride (a-2) having an alicyclic structure; and the maleic anhydride is not particularly limited, and an appropriate known method can be adopted. For example, first, the dimer acid-derived diamine (a-1), the tetracarboxylic dianhydride (a-2), and, if necessary, the organic diamine (a-3) are stirred in a solvent such as toluene, xylene, tetralin, N,N-dimethylacetamide, N-methyl-2-pyrrolidone, or a mixed solvent thereof at room temperature (about 23° C.) for 30 minutes to 60 minutes to synthesize a polyamic acid. Next, a maleic anhydride is added to the obtained polyamic acid, followed by stirring at room temperature (about 23° C.) for 30 minutes to 60 minutes, thereby synthesizing a polyamic acid in which a maleic acid is added to both terminals. Azeotropic solvent with water such as toluene is further added to the polyamic acid, and the mixture is refluxed at a temperature of 100° C. to 160° C. for 3 hours to 6 hours while removing the water produced by imidization to obtain the desired maleimide resin (A). In addition, a catalyst such as pyridine or methanesulfonic acid may be further added in such a method.

In a mixing of the raw materials in the reaction, a ratio of (a total of molar amounts of all diamines contained in the diamine (a-1) derived from a dimer acid and a molar amount of the organic diamine (a-3)): (a sum of molar amounts of all tetracarboxylic dianhydride (a-2) having an alicyclic structure and ½ of molar amount of the maleic anhydride) preferably satisfies 1:1. In addition, in a case where the organic diamine (a-3) is used, from the viewpoint that flexibility derived from a dimer acid is exhibited and a cured object having a lower elastic modulus tends to be obtained, a ratio of (molar amount of the organic diamine (a-3))/(molar amount of all diamines contained in the diamine (a-1) derived from a dimer acid) is preferably 1 or less, and more preferably 0.4 or less. In a case where the organic diamine (a-3) is used, a polymerization form of: an amic acid unit including the diamine (a-1) derived from a dimer acid and the tetracarboxylic dianhydride (a-2) having an alicyclic structure; and an amic acid unit including the organic diamine (a-3) and the tetracarboxylic dianhydride (a-2) having an alicyclic structure may be random polymerization or block polymerization.

The maleimide resin (A) thus obtained is preferably represented by the following formula (2).

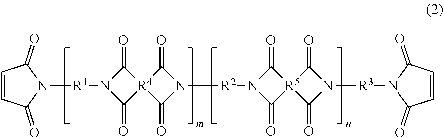

(In the general formula (2),
R¹ represents the divalent hydrocarbon group (a) derived from a dimer acid,
R² represents the divalent organic group (b) other than the divalent hydrocarbon group (a) derived from a dimer acid,
R³ represents any one selected from the group including the divalent hydrocarbon group (a) derived from a dimer acid and the divalent organic group (b) other than the divalent hydrocarbon group (a) derived from a dimer acid, and
R⁴ and R⁵ each independently represent one or more organic groups selected from:
   a tetravalent organic group having 4 to 40 carbon atoms (preferably 6 to 40 carbon atoms) and having a monocyclic or condensed polycyclic alicyclic structure;
   a tetravalent organic group having 8 to 40 carbon atoms in which organic groups having a monocyclic alicyclic structure are linked to one another directly or via a crosslinked structure; and
   a tetravalent organic group having 8 to 40 carbon atoms and having a semi-alicyclic structure including both an alicyclic structure and an aromatic ring. m is an integer of 1 to 30, n is an integer of 0 to 30, and R⁴ and R⁵ may be the same or different.)

The divalent hydrocarbon group (a) derived from a dimer acid in the formula (2) is as described above. In addition, in the present invention, the divalent organic group (b) other than the divalent hydrocarbon group (a) derived from a dimer acid in the formula (2) refers to a divalent residue obtained by removing two amino groups from the organic diamine (a-3). However, the divalent hydrocarbon group (a) derived from a dimer acid and the divalent organic group (b) in the same compound are not the same. Further, the tetravalent organic group in the formula (2) refers to a tetravalent residue obtained by removing two groups represented by —CO—O—CO- from the tetracarboxylic dianhydride.

In the formula (2), m represents the number of repeating units containing the divalent hydrocarbon group (a) derived from a dimer acid (hereinafter, referred to as “a dimer acid-derived structure” in some cases), and represents an integer of 1 to 30. In a case where the value of m exceeds the upper limit, the solubility in a solvent tends to decrease, and particularly the solubility in a developing solution at the time of development to be described below tends to decrease. In addition, the value of m is particularly preferably 3 to 10 from the viewpoint that the solubility in the developing solution at the time of development becomes suitable.

In the formula (2), n represents the number of repeating units containing the divalent organic group (b) (hereinafter, referred to as “an organic diamine-derived structure” in some cases), and represents an integer of 0 to 30. In a case where the value of n exceeds the upper limit, the flexibility of the obtained cured object is deteriorated, and a hard and brittle resin tends to be obtained. In addition, the value of n is particularly preferably 0 to 10 from the viewpoint that a cured object having a low elastic modulus tends to be obtained.

Further, in a case where m in the formula (2) is 2 or more, R¹ and R⁴ may be the same or different among the respective repeating units. In addition, in a case where n in the formula (2) is 2 or more, R² and R⁵ may be the same or different among the respective repeating units. Further, as the bismaleimide compound represented by the formula (2), the dimer acid-derived structure and the organic diamine-derived structure may be random or block.

In addition, in a case where the maleimide compound (A) according to the present invention is obtained from the diamine (a-1) derived from a dimer acid, the maleic anhydride, to the tetracarboxylic dianhydride (a-2) and, if necessary, the organic diamine (a-3), when a reaction rate is 100%, n and m can be represented by a mixing molar ratio of all diamines contained in the diamine (a-1) derived from a dimer acid, the organic diamine (a-3), the maleic anhydride, and the tetracarboxylic dianhydride (a-2). That is, (m+n):(m+n+2) is represented by (the total molar amount of all diamines contained in the diamine (a-1) derived from a dimer acid and the organic diamine (a-3)):(the total molar amount of the maleic anhydride and the tetracarboxylic dianhydride (a-2)), m:n is represented by (molar amount of all diamines contained in the diamine (a-1) derived from a dimer acid):(molar amount of the organic diamine (a-3)), and 2:(m+n) is represented by (molar amount of the maleic anhydride):(molar amount of the tetracarboxylic dianhydride (a-2)).

Further, in the maleimide resin (A), the sum (m+n) of m and n is preferably 2 to 30 from the viewpoint that a cured object having a lower elastic modulus tends to be obtained. In addition, the ratio (n/m) of n to m is preferably 1 or less, and more preferably 0.4 or less, from the viewpoint that the flexibility derived from a dimer acid is exhibited and a cured object having a lower elastic modulus tends to be obtained.

As the maleimide resin (A), the above may be used alone or in combination of two or more types thereof.

Next, a method for producing a maleimide resin (B) will be described.

As the maleimide resin (B), an aromatic amine resin represented by the following formula (8) can be used as a precursor.

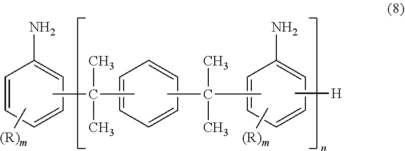

(In the formula (8), plural R each independently represent a hydrogen atom or an alkyl group having 1 to 5 carbon atoms. m represents an integer of 0 to 3. n represents the number of repetitions, and an average value thereof is 1<n<5.)

The aromatic amine resin represented by the formula (8) is more preferably represented by the following formula (9). This is because the crystallinity is reduced as compared with a case where the alkyl groups having 1 to 5 carbon atoms are para-substitution with respect to a benzene ring to which an amino group is not bonded in the formula (8).

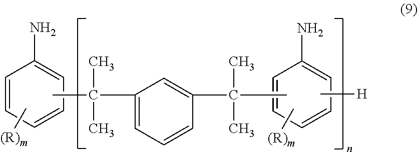

(In the formula (9), plural R each independently represent a hydrogen atom or an alkyl group having 1 to 5 carbon atoms. m represents an integer of 0 to 3. n represents the number of repetitions, and an average value thereof is 1<n<5.)

A method for producing the aromatic amine resin represented by the formula (8) or (9) is not particularly limited. For example, in a case where R is a hydrogen atom, the aromatic amine resin may be produced by using aniline as described in Patent Literature 4, and in a case where R is an alkyl group having 1 to 5 carbon atoms, the aromatic amine resin may be produced by reacting 2-alkylaniline such as 2-methylaniline, 2-ethylaniline, 2-propylaniline, 2-isopropylaniline, 2-butylaniline, 2-tert-butylaniline, and 2-amylaniline; with diisopropenylbenzene or di(α-hydroxyisopropyl)benzene at 180° C. to 250° C. in presence of an acidic catalyst as described in Patent Literature 5.

Examples of the acidic catalyst used at the time of synthesizing the aromatic amine resin represented by the formula (8) include hydrochloric acid, phosphoric acid, sulfuric acid, formic acid, zinc chloride, ferric chloride, aluminum chloride, p-toluenesulfonic acid, methanesulfonic acid, activated clay, and ion exchange resins. These may be used alone or in combination of two or types thereof. An amount of the catalyst used is generally 0.1 wt % to 50 wt %, and preferably 1 wt % to 30 wt %, with respect to the aniline used. In a case where the amount of the catalyst is extremely large, the viscosity of the reaction solution is too high, and stirring becomes difficult. In a case where the amount of the catalyst is extremely small, the reaction proceeds slowly.

If necessary, the reaction may be performed using an organic solvent such as toluene or xylene, or may be performed without a solvent. For example, in a case where an acidic catalyst is added to a mixed solution of 2-alkylaniline and a solvent, and thereafter, the catalyst contains water, it is preferable to azeotropically remove water from the system. Thereafter, diisopropenylbenzene or di(α-hydroxyisopropyl)benzene is added, then the temperature is increased while removing the solvent from the system, and the reaction is performed at 140° C. to 220° C., and preferably 160° C. to 200° C. for 5 hours to 50 hours, and preferably 5 hours to 30 hours. Since water is by-produced when di(α-hydroxyisopropyl)benzene is used, the water is removed from the system while being azeotroped with the solvent during heating. After completion of the reaction, the acidic catalyst is neutralized with an alkaline aqueous solution, a water-insoluble organic solvent is added to an oil layer, and water washing is repeated until the wastewater becomes neutral, followed by removing the solvent and excess aniline derivatives under heating and reduced pressure. In a case where activated clay or an ion exchange resin is used, the reaction solution is filtered after completion of the reaction to remove the catalyst.

The maleimide resin (B) is obtained by subjecting the aromatic amine resin represented by the formula (8) and obtained by the above steps to an addition reaction or dehydration condensation reaction with a maleic acid or a maleic anhydride (hereinafter also referred to as “maleic anhydride”) in the presence of a solvent and a catalyst.

The solvent used in the reaction is a water-insoluble solvent because it is necessary to remove water generated during the reaction from the system. Examples thereof include aromatic solvents such as toluene and xylene, aliphatic solvents such as cyclohexane and n-hexane, ethers such as diethyl ether and diisopropyl ether, ester-based solvents such as ethyl acetate and butyl acetate, and ketone-based solvents such as methyl isobutyl ketone and cyclopentanone, but the solvent is not limited thereto, and may be a combination of two or more types thereof.

In addition to the water-insoluble solvent, an aprotic polar solvent may be used in combination. Examples thereof include dimethyl sulfone, dimethyl sulfoxide, dimethylformamide, dimethylacetamide, 1,3-dimethyl-2-imidazolidinone, and N-methyl-2-pyrrolidone, and may be a combination of two or more types thereof. In a case where an aprotic polar solvent is used, it is preferable to use a solvent having a boiling point higher than that of the water-insoluble solvent used in combination.

In addition, the catalyst used in the reaction is an acidic catalyst, and is not particularly limited. Examples thereof include p-toluenesulfonic acid, hydroxy-p-toluenesulfonic acid, methanesulfonic acid, sulfuric acid, and phosphoric acid. An amount of the acid catalyst used is generally 0.1 wt % to 10 wt %, and preferably 1 wt % to 5 wt %, with respect to the aromatic amine resin.

For example, the aromatic amine resin represented by the formula (8) is dissolved in toluene and N-methyl-2-pyrrolidone, a maleic anhydride is added thereto to generate an amic acid, and thereafter, p-toluenesulfonic acid is added thereto, followed by performing the reaction while removing water generated from the system under reflux conditions.

Alternatively, a maleic anhydride is dissolved in toluene, an N-methyl-2-pyrrolidone solution of the aromatic amine resin represented by the formula (8) is added under stirring to generate an amic acid, and thereafter p-toluenesulfonic acid is added thereto, followed by performing the reaction while removing water generated from the system under reflux conditions.

Alternatively, a maleic anhydride is dissolved in toluene, p-toluenesulfonic acid is added thereto, and in a stirred and refluxed state, a toluene solution of the aromatic amine resin represented by the formula (8) is dropped. The reaction is carried out while removing the water that azeotropes during the process from the system and returning toluene to the system (the above is a first stage reaction).

In any method, the maleic anhydride is generally used in an amount of 1 to 3 equivalents, and preferably in an amount of 1.2 to 2.0 equivalents, relative to the amino group of the aromatic amine resin represented by the formula (8).

In order to reduce the amount of the unclosed amic acid, water is added to the reaction solution after the maleimidation reaction listed above to separate the reaction solution into a resin solution layer and a water layer. Excessive maleic acid, maleic anhydride, aprotic polar solvent, catalyst and the like are dissolved in a water layer side, and thus are separated and removed, and further, the same operation is repeated to thoroughly remove excessive maleic acid, maleic anhydride, aprotic polar solvent, and catalyst. The catalyst is added again to the maleimide resin solution of the organic layer from which excessive maleic acid, maleic anhydride, aprotic polar solvent, and catalyst are removed, followed by performing a dehydration-ring closure reaction on the residual amic acid again under heating and refluxing conditions, thereby obtaining a maleimide resin solution having a low acid value (the above is a second stage reaction).

The time of the re-dehydration-ring closure reaction is generally 1 hour to 10 hours, and preferably 1 hour to 5 hours, and the above-described aprotic polar solvent may be added as necessary. After completion of the reaction, the maleimide resin solution is cooled and repeatedly washed with water until the washing water becomes neutral. Thereafter, the solvent may be distilled off after removing water by azeotropic dehydration under heating and reduced pressure or another solvent may be added to adjust the maleimide resin solution to a resin solution having a desired concentration, or the solvent may be completely distilled off to obtain a solid resin, which may be taken out.

The maleimide resin (B) obtained by the above-described production method has the structure represented by the following formula (1).

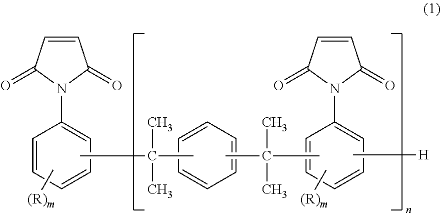

(In the formula (1), plural R each independently represent a hydrogen atom or an alkyl group having 1 to 5 carbon atoms. n represents the number of repetitions, and an average value thereof is 1<n<5.)

In the formula (1), m represents generally 0 to 3, preferably 0 to 2, and more preferably 0. R is generally a hydrogen atom or an alkyl group having 1 to 5 carbon atoms, preferably a hydrogen atom, a methyl group, or an ethyl group, and more preferably a hydrogen atom. In a case where m is more than 3 or in a case where R is an alkyl group having 6 or more carbon atoms, the electric properties may be deteriorated by molecular vibration when the alkyl group is exposed to a radio frequency.

In the formula (1), the value of n can be calculated from a value of a number average molecular weight obtained by the measurement of gel permeation chromatography (GPC, detector: RI) of the maleimide resin (B), but can be approximately considered to be substantially equivalent to the value of n calculated from a measurement result of the GPC of the aromatic amine resin represented by the formula (8) as the raw material. A content of the component where n=1 in the formula (1) can be determined by gel permeation chromatography (GPC, detector: RI) analysis.

In a case where n=1 in the formula (1), the solubility in a solvent is low, and in a case where n is 5 or more, the fluidity at the time of molding becomes poor, and the properties as a cured object cannot be sufficiently exhibited.

The maleimide resin (B) preferably has a molecular weight distribution. The content of the component where n=1 in the formula (1) as determined by GPC analysis (RI) is preferably 98 area % or less, more preferably 20 area % to 98 area %, still more preferably 30 area % to 95 area %, and particularly preferably 50 area % to 90 area %. In a case where the content of the component where n=1 is 98 area % or less, the heat resistance becomes good and the solubility is also improved. On the other hand, a lower limit of the component where n=1 may be 0 area %, but in a case of being 30 area % or more, the viscosity of the resin solution decreases, and the impregnation property becomes good.

A softening point of the maleimide resin (B) is preferably 50° C. to 150° C., more preferably 80° C. to 120° C., still more preferably 90° C. to 110° C., and particularly preferably 95° C. to 105° C. In addition, a melt viscosity at 150° C. is 0.05 Pa·s to 100 Pa·s, and preferably 0.1 Pa·s to 40 Pa·s.

The maleimide resin (B) more preferably has a structure represented by the formula (10). The reason is that in a case where R in the formula (1) is an alkyl group having 1 to 5 carbon atoms, the crystallinity is reduced as compared with a case where the propyl groups are para-substitution with respect to a benzene ring to which a maleimide group is not bonded.

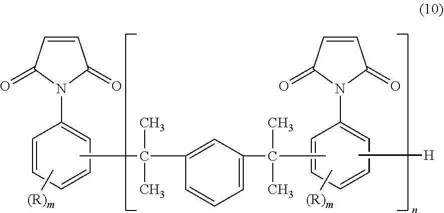

(In the formula (10), plural R each independently represent a hydrogen atom or an alkyl group having 1 to 5 carbon atoms. m represents an integer of 0 to 3. n represents the number of repetitions, and an average value thereof is 1<n<5.)

Preferable ranges of R and m in the formula (10) are the same as those in the formula (1).

The content of the maleimide resin (A) is preferably 30 wt % or more and less than 95 wt %, more preferably 40 wt % or more and less than 90 wt %, and still more preferably 50 wt % or more and less than 90 wt %, based on a total amount of the curable resin composition.

In addition, the content of the maleimide resin (B) is preferably 3 wt % or more and less than 60 wt %, more preferably 5 wt % or more and less than 50 wt %, and still more preferably 10 wt % or more and less than 40 wt %, based on the total amount of the curable resin composition. In addition, the content of the maleimide resin (A) is preferably larger than that of the maleimide resin (B). In the above range, the physical properties of the cured object tend to be high mechanical strength, high peel strength, and good heat resistance while maintaining flexibility. The “total amount of the curable resin composition” does not contain the amount of the solvent.

The maleimide resin (A) and the maleimide resin (B) have excellent compatibility. In the present application, “compatible” means that, when a curable resin composition formed by uniformly mixing two or more types of resins is liquid, the haze of the solution is less than 50; or when a cured object is formed, it means that the glass transition temperature (Tg) of the curable resin composition is measured only at one point. In other words, in the “incompatible” state, the haze is 50 or more in the case of the liquid; or plural Tgs are measured even if the resins are uniformly mixed in the cured object.

The compatibility and the haze of the curable resin composition according to the present invention are measured as follows.

### [Compatibility]

When the curable resin composition is visually observed, a curable resin composition having no precipitate or the like and capable of being applied to a base material or the like is evaluated as having good compatibility, and a curable resin composition having a precipitate or the like and being difficult to be applied to a base material or the like is evaluated as having poor compatibility.

### [Haze Value]

The curable resin composition was put into a square cell having an optical path length of 10 mm, and the curable resin composition was irradiated with light under a condition of 25° C. using a simultaneous measurement instrument for color and turbidity (COH 400, manufactured by Nippon Denshoku Industries Co., Ltd), thereby determining the haze value using following calculation formula (1) by a ratio of a diffused light transmittance (Td) of transmitted light diffused by the sheet to a total light transmittance (Tt) representing a total amount of transmitted light in accordance with JIS K7136. The total light transmittance (Tt) is a sum of the diffused light transmittance (Td) and a parallel light transmittance (Tp) transmitted coaxially with the incident light.

Haze(H)=Td/Tt×100 (1)

The curable resin composition according to the present invention may contain a thermosetting resin (C) as a thermosetting component other than the maleimide resins (A) and (B) according to the present invention.

In a case where the thermosetting resin (C) is blended, a blending amount thereof is not particularly limited, but is preferably 0.1 to 10 times, and more preferably 0.2 to 4 times the total amount of the maleimide resins (A) and (B) in terms of weight ratio.

The thermosetting resin (C) is not particularly limited as long as it is a compound containing a functional group (or structure) capable of crosslinking reaction with a maleimide resin such as an amino group, a cyanate group, a phenolic hydroxy group, an alcoholic hydroxy group, an allyl group, a methallyl group, an acrylic group, a methacrylic group, a vinyl group, and a conjugated diene group. Specific examples thereof include amine compounds, cyanate ester compounds, epoxy resins, phenolic resins, oxetane resins, carbodiimide compounds, benzoxazine compounds, compounds containing an ethylenically unsaturated group, and compounds containing an acid anhydride group. In addition, a maleimide compound other than the maleimide resins (A) and (B) according to the present invention may be used in combination.

As the amine compound that may be blended with the curable resin composition according to the present invention, a known amine compound can be used. Specific examples of the amine compound include, but are not limited to, the aromatic amine resin represented by the formula (8), diethylenetriamine, triethylenetetramine, tetraethylenepentamine, m-xylenediamine, trimethylhexamethylenediamine, 2-methylpentamethylenediamine, diethylaminopropylamine, isophoronediamine, 1,3-bisaminomethylcyclohexane, bis(4-aminocyclohexyl)methane, bis(4-amino-3-methylcyclohexyl)methane, norbornenediamine, 1,2-diaminocyclohexane, diaminodiphenylmethane, metaphenylenediamine, diaminodiphenylsulfone, dicyandiamide, polyoxypropylenediamine, polyoxypropylenetriamine, N-aminoethylpiperazine, and aniline/formalin resin. These may be used alone or in combination with two or more types thereof. In addition, the aromatic amine resin described in the claims of Patent Literature 3 is particularly preferable because it is excellent in low hygroscopicity, flame resistance, and dielectric properties.

In a case where the amine compound is blended, a blending amount thereof is not particularly limited, but is preferably 0.1 times to 10 times, and more preferably 0.2 times to 4 times the maleimide resins (A) and (B) in terms of weight ratio.

As the maleimide compound other than the maleimide resins (A) and (B) which may be blended in the curable resin composition according to the present invention, a known maleimide compound can be used. Specific examples of the maleimide compound are not particularly limited as long as it is a compound containing one or more maleimide groups in a molecule. Specific examples thereof include N-phenylmaleimide, N-cyclohexylmaleimide, N-hydroxyphenylmaleimide, N-carboxyphenylmaleimide, N-(4-carboxy-3-hydroxyphenyl)maleimide, 6-maleimidehexanoic acid, 4-maleimidobutyric acid, bis(4-maleimidophenyl)methane, 2,2-bis14-(4-maleimidophenoxy)-phenyll propane, 4,4-diphenylmethane bismaleimide, bis(3,5-dimethyl-4-maleimidephenyl)methane, bis(3-ethyl-5-methyl-4-maleimidephenyl)methane, bis(3,5-diethyl-4-maleimidephenyOmethane, phenylmethane maleimide, o-phenylene bismaleimide, m-phenylene bismaleimide, p-phenylene bismaleimide, o-phenylene biscitraconimide, m-phenylene biscitraconimide, p-phenylene biscitraconimide, 2,2-bis(4-(4-maleimidephenoxy)-phenyl)propane, 3,3-dimethyl-5,5-diethyl-4,4-diphenylmethane bismaleimide, 4-methyl-1,3-phenylene bismaleimide, 1,2-bismaleimide ethane, 1,4-bismaleimide butane, 1,6-bismaleimide hexane, 1,6-bismaleimide-(2,2,4-trimethyl)hexane, 1,8-bismaleimide-3,6-dioxaoctane, 1,11-bismaleimide-3,6,9-trioxaundecane, 1,3-bis(maleimidemethyl)cyclohexane, 1,4-bis(maleimidemethyl)cyclohexane, 4,4-diphenylether bismaleimide, 4,4-diphenylsulfone bismaleimide, 1,3-bis(3-maleimidephenoxy)benzene, 1,3-bis(4-maleimidephenoxy)benzene, 4,4-diphenylmethane biscitraconimide, 2,2-bis[4-(4-citraconimide phenoxy)phenyl]propane, bis(3,5-dimethyl-4-citraconimide phenyl)methane, bis(3-ethyl-5-methyl-4-citraconimide phenyl)methane, bis(3,5-diethyl-4-citraconimide phenyl)methane, polyphenylmethanemaleimide, polyphenylmethanemaleimide, a maleimide compound represented by the following formula (5), a maleimide compound represented by the following formula (11), a maleimide compound represented by the following formula (12), a maleimide compound represented by the following formula (13), a maleimide compound represented by the following formula (15) such as a maleimide compound represented by the following formula (14), a maleimide compound represented by the following formula (16), a maleimide compound represented by the following formula (17), a maleimide compound represented by the following formula (18), a maleimide compound represented by the following formula (19), fluorescein-5-maleimide, and a prepolymer of these maleimide compounds, or a prepolymer of a maleimide compound and an amine compound. These other maleimide compounds may be used alone or in combination of two or more types thereof as appropriate.

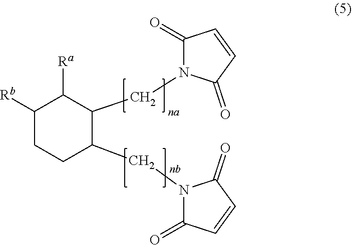

(In the formula (5), R^{a} and R^{b} each independently represents a linear or branched alkyl group having 1 to 16 carbon atoms, or a linear or branched alkenyl group having 1 to 16 carbon atoms. na represents the number of 1 to 16, and nb represents the number of 1 to 16. na and nb may be the same or different.)

In the formula (5), R^{a} and R^{b} each independently represents a linear or branched alkyl group having 1 to 16 carbon atoms, or a linear or branched alkenyl group having 1 to 16 carbon atoms, and are preferably a linear or branched alkyl group, and more preferably a linear alkyl group because the dielectric properties can be deteriorated. The alkyl group preferably has 1 to 16 carbon atoms, and more preferably 4 to 12 carbon atoms. The alkenyl group preferably has 1 to 16 carbon atoms, and more preferably 4 to 12 carbon atoms.

The alkyl group in the formula (5) is preferably an n-heptyl group, an n-octyl group, or an n-nonyl group, and more preferably an n-octyl group, from the viewpoint of exhibiting excellent photocurability. The alkenyl group is preferably a 2-heptenyl group, a 2-octenyl group, or a 2-nonenyl group, and more preferably a 2-octenyl group.

In the formula (5), na is 1 or more, preferably 2 to 16, and more preferably 3 to 14. nb is 1 or more, preferably 2 to 16, and more preferably 3 to 14. na and nb may be the same or different.

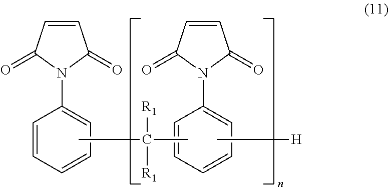

In the formula (11), plural R₁ each independently represents a hydrogen atom or a methyl group. n represents an integer of 1 or more, preferably an integer of 1 to 10, and more preferably an integer of 1 to 5.

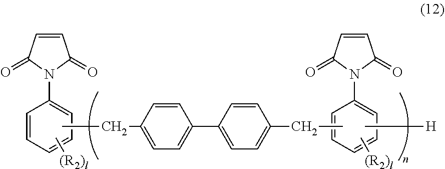

In the formula (12), R₂ each independently represents a hydrogen atom, an alkyl group having 1 to 5 carbon atoms, or a phenyl group, 1 each independently represents an integer of 1 to 3, and n represents an integer of 1 to 10. Examples of the alkyl group having 1 to 5 carbon atoms include a methyl group, an ethyl group, an n-propyl group, an isopropyl group, an n-butyl group, an isobutyl group, a sec-butyl group, a t-butyl group, an n-pentyl group, and a neopentyl group.

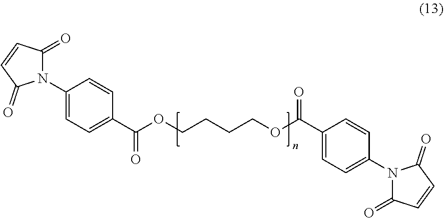

In the formula (13), n is 1 or more, preferably 1 to 21, and more preferably 1 to 16.

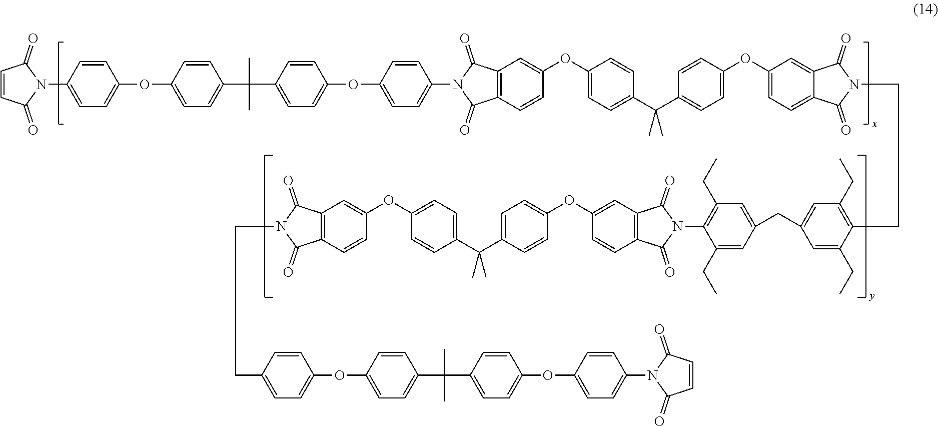

In the formula (14), the number of x is 10 to 35, and the number of y is 10 to 35.

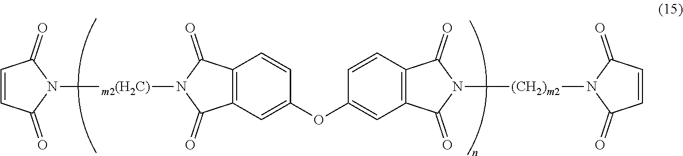

In the formula (15), n represents an integer of 1 to 10, and m2 represents an integer of 8 to 40.

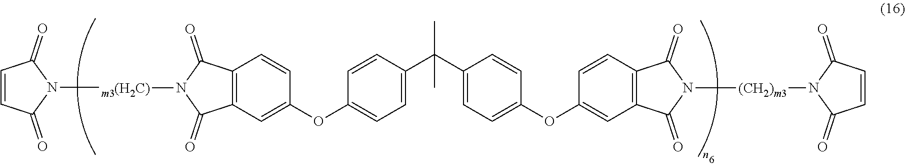

In the formula (16), n₆ represents an integer of 1 to 10, and m3 represents an integer of 8 to 40.

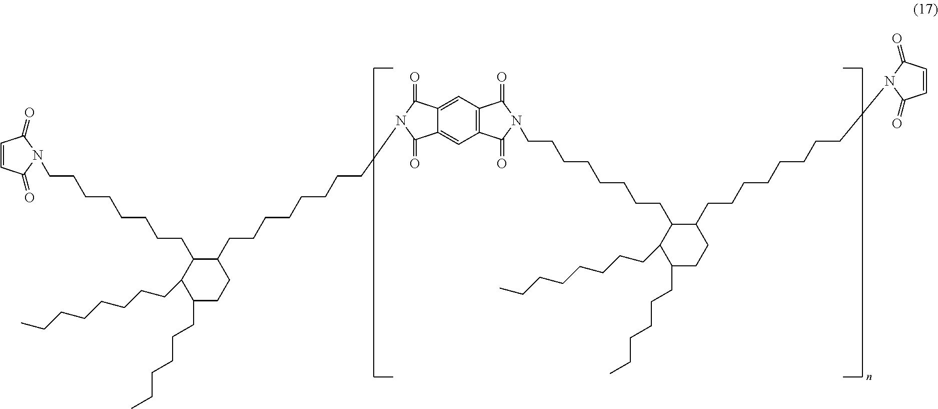

In the formula (17), n represents an integer of 1 or more, and preferably an integer of 1 to 10.

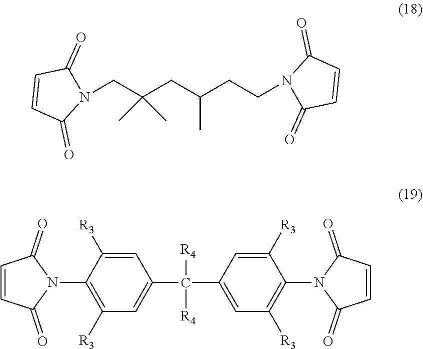

In the formula (19), R₃ each independently represents a hydrogen atom, a methyl group, or an ethyl group, and R₄ each independently represents a hydrogen atom or a methyl group.

As the other maleimide compound, a commercially available product can also be used.

Examples of the maleimide compound represented by the formula (5) include BMI-689 (trade name) manufactured by DESIGNER MOLECURES Inc.

Examples of the maleimide compound represented by the formula (11) include BMI-2300 (trade name) manufactured by Daiwa Kasei Industry Co., Ltd.

Examples of the maleimide compound represented by the formula (12) include MIR-3000 (trade name) manufactured by Nippon Kayaku Co., Ltd.

Examples of the maleimide compound represented by the formula (13) include BMI-1000P (trade name, n=13.6 (average) in the formula (13)) manufactured by K-I Chemical Industry Co., Ltd., BMI-650P (trade name, n=8.8 (average) in the formula (13)) manufactured by K-I Chemical Industry Co., Ltd., BMI-250P (trade name, n=3 to 8 (average) in the formula (13)) manufactured by K-I Chemical Industry Co., Ltd., and CUA-4 (trade name, n=1 in the formula (13)) manufactured by K-I Chemical Industry Co., Ltd.

Examples of the maleimide compound represented by the formula (14) include BMI-6100 (trade name, x=18, y=18 in the formula (14)) manufactured by Designer Molecules Inc.

Examples of the maleimide compound represented by the formula (15) include BMI-1500 (trade name, n=1.3 in the formula (15), functional group equivalent: 754 g/eq.) manufactured by Designer Molecules Inc.

As the maleimide compound represented by the formula (16), a commercially available product can also be used, and examples thereof include BMI-1700 (trade name) manufactured by Designer Molecules Inc. (DMI).

As the maleimide compound represented by the formula (17), a commercially available product can be used, and examples thereof include BMI-3000 (trade name) manufactured by Designer Molecules Inc. (DMI), BMI-5000 (trade name) manufactured by

Designer Molecules Inc. (DMI), and BMI-9000 (trade name) manufactured by Designer Molecules Inc. (DMI).

As the maleimide compound represented by the formula (18), a commercially available product may be used, and examples thereof include BMI-TMH (trade name) manufactured by Daiwa Kasei Industry Co., Ltd.

As the maleimide compound represented by the formula (19), a commercially available product can also be used, and examples thereof include BMI-70 (trade name) manufactured by K-I Chemical Industry Co., Ltd.

These other maleimide compounds may be used alone or in combination of two or more types thereof as appropriate.

In the curable resin composition according to the present invention, a total content of the other maleimide compounds is not particularly limited, but from the viewpoint of obtaining more excellent adhesiveness to a chip, a substrate, and the like, is preferably 0.01 parts by mass to 95 parts by mass, more preferably 0.1 parts by mass to 90 parts by mass, still more preferably 5 parts by mass to 80 parts by mass, and yet still more preferably 1 part by mass to 50 parts by mass with respect to 100 parts by mass of the resin solid content in the curable resin composition according to the present invention.

As the cyanate ester compound that may be blended in the curable resin composition according to the present invention, a known cyanate ester compound can be used. Specific examples of the cyanate ester compound include, but are not limited to, cyanate ester compounds obtained by reacting a polycondensate of phenols and various aldehydes, a polymer of phenols and various diene compounds, a polycondensate of phenols and ketones, and a polycondensate of bisphenol and various aldehydes with a cyanogen halide. These may be used alone or in combination of two or more types thereof. Examples of the phenols include a phenol, alkyl-substituted phenols, aromatic-substituted phenols, naphthols, alkyl-substituted naphthols, dihydroxybenzene, alkyl-substituted dihydroxybenzene, and dihydroxynaphthalene. Examples of the various aldehydes include formaldehyde, acetaldehyde, alkyl aldehyde, benzaldehyde, alkyl-substituted benzaldehyde, hydroxy benzaldehyde, naphthaldehyde, glutaraldehyde, phthalaldehyde, crotonaldehyde, and cinnamaldehyde. Examples of the various diene compounds include dicyclopentadiene, terpenes, vinylcyclohexene, norbornadiene, vinyl norbornene, tetrahydroindene, divinylbenzene, divinylbiphenyl, diisopropenyl biphenyl, butadiene, and isoprene. Examples of the ketones include acetone, methyl ethyl ketone, methyl isobutyl ketone, acetophenone, and benzophenone. In addition, the cyanate ester compound whose synthesis method is described in JP2005-264154A is particularly preferable as a cyanate ester compound because it is excellent in low hygroscopicity, flame resistance, and dielectric properties.

Specific examples of the cyanate ester compound that may be blended in the curable resin composition according to the present invention include cyanatobenzene, 1-cyanato-2-, 1-cyanato-3-, or 1-cyanato-4-methyl benzene, 1-cyanato-2-, 1-cyanato-3-, or 1-cyanato-4-methoxybenzene, 1-cyanato-2,3-, 1-cyanato-2,4-, 1-cyanato-2,5-, 1-cyanato-2,6-, 1-cyanato-3,4-, or 1-cyanato-3,5-dimethylbenzene, cyanato ethylbenzene, cyanato butylbenzene, cyanato octylbenzene, cyanato nonylbenzene, 2-(4-cyanophenyl)-2-phenylpropane (cyanate of 4-α-cumylphenol), 1-cyanato-4-cyclohexylbenzene,1-cyanato-4-vinyl benzene, 1-cyanato-2- or 1-cyanato-3-chlorobenzene, 1-cyanato-2,6-dichlorobenzene, 1-cyanato-2-methyl-3-chlorobenzene, cyanato nitrobenzene, 1-cyanato-4-nitro-2-ethylbenzene,1-cyanato-2-methoxy-4-allylbenzene (cyanate of eugenol), methyl (4-cyanatophenyl)sulfide, 1-cyanato-3-trifluoromethylbenzene, 4-cyanatobiphenyl, 1-cyanato-2- or 1-cyanato-4-acetylbenzene, 4-cyanato benzaldehyde, 4-cyanatobenzoic acid methyl ester, 4-cyanatobenzoic acid phenyl ester, 1-cyanato-4-acetoaminobenzene, 4-cyanato benzophenone, 1-cyanato-2,6-di-tert-butylbenzene, 1,2-dicyanatobenzene, 1,3-dicyanatobenzene, 1,4-dicyanatobenzene, 1,4-dicyanato-2-tert-butylbenzene, 1,4-dicyanato-2,4-dimethylbenzene, 1,4-dicyanato-2,3,4-dimethylbenzene, 1,3-dicyanato-2,4,6-trimethylbenzene, 1,3-dicyanato-5-methylbenzene, 1-cyanato or 2-cyanatonaphthalene, 1-cyanato-4-methoxynaphthalene, 2-cyanato-6-methoxynaphthalene, 2-cyanato-7-methoxynaphthalene, 2,2′-dicyanato-1,1′-binaphthyl, 1,3-, 1,4-, 1,5-, 1,6-, 1,7-, 2,3-, 2,6-,or 2,7-dicyanatonaphthalene, 2,2′- or 4,4′-dicyanatobiphenyl, 4,4′-dicyanatooctafluorobiphenyl, 2,4′- or 4,4′-dicyanatodiphenylmethane, bis(4-cyanato-3,5-dimethylphenyl)methane, 1,1-bis(4-cyanatophenypethane, 1,1-bis(4-cyanatophenyl)propane, 2,2-bis(4-cyanatophenyl)propane, 2,2-bis(4-cyanato-3-methylphenyl)propane, 2,2-bis(2-cyanato-5-biphenylyl)propane, 2,2-bis(4-cyanatophenyl)hexafluoropropane, 2,2-bis(4-cyanato-3,5)-dimethylphenyl)propane, 1,1-bis(4-cyanatophenyl)butane, 1,1-bis(4-cyanatophenyl)isobutane, 1,1-bis(4-cyanatophenyOpentane, 1,1-bis(4-cyanatophenyl)-3-methylbutane, 1,1-bis(4-cyanatophenyl)-2-methylbutane, 1,1-bis (4-cyanatophenyl)-2,2-dimethylpropane, 2,2-bis(4-cyanatophenyl)butane, 2,2-bis(4-cyanatophenyl)pentane, 2,2-bis(4-cyanatophenyl)hexane, 2,2-bis(4-cyanatophenyl)-3-methylbutane, 2,2-bis(4-cyanatophenyl)-4-methylpentane, 2,2-bis(4-cyanatophenyl)-3,3-dimethylbutane, 3,3-bis(4-cyanatophenyl)hexane, 3,3-bis(4-cyanatophenyl)heptane, 3,3-bis(4-cyanatophenyl)octane, 3,3-bis(4-cyanatophenyl)-2-methylpentane, 3,3-bis(4-cyanatophenyl)-2-methylhexane, 3,3-bis(4-cyanatophenyl)-2,2-dimethylpentane, 4,4-bis(4-cyanatophenyl)-3-methylheptane, 3,3-bis(4-cyanatophenyl)-2-methylheptane, 3,3-bis(4-cyanatophenyl)-2,2-dimethylhexane, 3,3-bis(4-cyanatophenyl)-2,4-dimethylhexane, 3,3-bis(4-cyanatophenyl)-2,2,4-trimethylpentane, 2,2-bis(4-cyanatophenyl)-1,1,1,3,3,3-hexafluoropropane, bis(4-cyanatophenyl)phenylmethane, 1,1-bis(4-cyanatophenyl)-1-phenylethane, bis(4-cyanatophenyl)biphenylmethane, 1,1-bis(4-cyanatophenyl)cyclopentane, 1,1-bis(4-cyanatophenyl)cyclohexane, 2,2-bis(4-cyanato-3-isopropylphenyl)propane, 1,1-bis(3-cyclohexyl-4-cyanatophenyl)cyclohexane, bis(4-cyanatophenyl)diphenylmethane, bis(4-cyanatophenyl)-2,2-dichloroethylene, 1,3-bis[2-(4-cyanatophenyl)-2-propyl]benzene, 1,4-bis[2-(4-cyanatophenyl)-2-propyl]benzene, 1,1-bis(4-cyanatophenyl)-3,3,5-trimethylcyclohexane, 4-[bis(4-cyanatophenyOmethyl] biphenyl, 4,4-dicyanato benzophenone, 1,3-bis(4-cyanatophenyl)-2-propen-1-one, bis(4-cyanatophenyl)ether, bis(4-cyanatophenyl)sulfide, bis(4-cyanatophenyl)sulfone, 4-cyanatobenzoic acid-4-cyanatophenyl ester(4-cyanatophenyl-4-cyanatobenzoate), bis-(4-cyanatophenyl)carbonate, 1,3-bis(4-cyanatophenyl)adamantane, 1,3-bis(4-cyanatophenyl)-5,7-dimethyladamantane, 3,3-bis(4-cyanatophenyl)isobenzofuran-1(3H)-one (cyanate of phenolphthalein), 3,3-bis(4-cyanato-3-methylphenyl)isobenzofuran-1(3H)-one (cyanate of o-cresolphthalein), 9,9′-bis(4-cyanatophenyl)fluorene, 9,9-bis(4-cyanato)-3-methylphenyl)fluorene, 9,9-bis(2-cyanato-5-biphenylyl)fluorene, tris(4-cyanatophenyl)methane, 1,1,1-tris(4-cyanatophenypethane, 1,1,3-tris(4-cyanatophenyl)propane, α,α,α′-tris(4-cyanatophenyl)-1-ethyl-4-isopropylbenzene, 1,1,2,2-tetrakis(4-cyanatophenyl)ethane, tetrakis(4-cyanatophenyl)methane, 2,4,6-tris(N-methyl-4-cyanatoanilino)-1,3,5-triazine, 2,4-bis(N-methyl-4-cyanatoanilino)-6-(N-methylanilino)-1,3,5-triazine, bis(N-4-cyanato-2-methylphenyl)-4,4′-oxydiphthalimide, bis(N-3-cyanato-4-methylphenyl)-4,4′-oxydiphthalimide, bis(N-4-cyanatophenyl)-4,4′-oxydiphthalimide, bis(N-4-cyanato-2-methylphenyl)-4,4′-(hexafluoroisopropylidene)diphthalimide, tris(3,5-dimethyl-4-cyanatobenzypisocyanurate, 2-phenyl-3,3-bis(4-cyanatophenyl)phthalimidine, 2-(4-methylphenyl)-3,3-bis(4-cyanatophenyl)phthalimidine, 2-phenyl-3,3-bis(4-cyanato-3-methylphenyl)phthalimidine, 1-methyl-3,3-bis(4-cyanatophenypindolin-2-one, and 2-phenyl-3,3-bis (4-cyanatophenyl)indolin-2-one.

In a case where the cyanate ester compound is blended, a blending amount thereof is not particularly limited, but is preferably 0.1 times to 10 times, and more preferably 0.2 times to 4 times the total amount of the maleimide resins (A) and (B) in terms of weight ratio. In a case where the blending amount of the cyanate ester compound is in the range of 0.1 times to 10 times, the heat resistance and the dielectric properties of the cured object are excellent.

In the curable resin composition according to the present invention, an epoxy resin may be further blended. As the epoxy resin that may be blended, a known epoxy resin can be used. Specific examples of the epoxy resin include, but are not limited to, glycidyl ether-based epoxy resins in which a polycondensate of phenols and various aldehydes, a polymer of phenols and various diene compounds, a polycondensate of phenols and ketones, a polycondensate of bisphenols and various aldehydes, an alcohol, and the like are glycidylated; alicyclic epoxy resins typified by 4-vinyl-1-cyclohexene diepoxide and 3,4-epoxycyclohexylmethyl-3,4′-epoxycyclohexane carboxylate; glycidylamine-based epoxy resins typified by tetraglycidyl diaminodiphenylmethane (TGDDM) and triglycidyl p-aminophenol; and glycidyl ester-based epoxy resins. These may be used alone or in combination of two or more types thereof. In addition, an epoxy resin obtained by subjecting a phenol aralkyl resin obtained by subjecting a phenol and a bishalogenomethyl aralkyl derivative or an aralkyl alcohol derivative to a condensation reaction to a dehydrochlorination reaction with epichlorohydrin is excellent in low hygroscopicity, flame resistance, and dielectric properties, and thus is particularly preferable as an epoxy resin.

In a case where the epoxy resin is blended, a blending amount thereof is not particularly limited, but is preferably 0.1 times to 10 times, and more preferably 0.2 times to 4 times the maleimide resin in terms of weight ratio. In a case where the blending amount of the epoxy resin is in the range of 0.1 times to 10 times, the strength and the dielectric properties of the cured object are excellent.

In the curable resin composition according to the present invention, a compound having a phenolic resin may be further blended. As the phenolic resin that may be blended, a known phenolic resin can be used. Specific examples of the phenolic resin include, but are not limited to:
a polycondensate of bisphenols (bisphenol A, bisphenol F, bisphenol S, biphenol, bisphenol

AD, and the like), phenols (phenol, alkyl-substituted phenol, aromatic substituted phenol, naphthol, alkyl-substituted naphthol, dihydroxybenzene, alkyl-substituted dihydroxybenzene, dihydroxynaphthalene, and the like), and various aldehydes (formaldehyde, acetaldehyde, alkylaldehyde, benzaldehyde, alkyl-substituted benzaldehyde, hydroxybenzaldehyde, naphthaldehyde, glutaraldehyde, phthalaldehyde, crotonaldehyde, cinnamaldehyde, and the like);
a polymer of phenols and various diene compounds (dicyclopentadiene, terpenes, vinyl cyclohexene, norbornadiene, vinyl norbornene, tetrahydro indene, divinylbenzene, divinylbiphenyl, diisopropenyl biphenyl, butadiene, isoprene, or the like);
a polycondensate of phenols and a ketones (acetone, methyl ethylketone, methyl isobutyl ketone, acetophenone, benzophenone, and the like);
a polycondensate of phenols and aromatic dimethanols (benzenedimethanol, α,α,aα′,α′-benzenedimethanol, biphenyldimethanol, α,α,α′,α′-biphenyldimethanol, and the like);
a polycondensate of phenols and aromatic dichloromethyls (α,α′-dichloroxylene, bischloromethylbiphenyl, and the like);
a polycondensate of bisphenols and various aldehydes; and a modified product thereof. These may be used alone or in combination of two or more types thereof. In addition, a phenol aralkyl resin obtained by subjecting phenols and the bishalogenomethyl aralkyl derivative or the aralkyl alcohol derivative to a condensation reaction is excellent in low hygroscopicity, flame resistance, and dielectric properties, and thus is particularly preferable as a phenolic resin. In addition, the phenolic resin containing an allyl group or a methallyl group is preferable because the reactivity to a maleimide group is better than that of a hydroxy group, and thus the curing rate is increased, the number of crosslinking points is increased, and the strength and the heat resistance are increased. In addition, an allyl ether obtained by allylation of the hydroxy group of the phenolic resin or a methallyl ether obtained by methallylation of the hydroxy group of the phenolic resin may also be blended, and since the hydroxy group is etherified, the water absorbability is low.

In a case where the phenolic resin is blended, a blending amount thereof is not particularly limited, but is preferably 0.1 times to 10 times, and more preferably 0.2 times to 4 times the total amount of the maleimide resins (A) and (B) in terms of weight ratio. In a case where the blending amount of the phenolic resin is in the range of 0.1 times to 10 times, the adhesive strength and the dielectric properties of the cured object are excellent.

As the oxetane resin that may be blended in the curable resin composition according to the present invention, a generally known oxetane resin can be used. Examples thereof include, but are not particularly limited to: alkyloxetanes such as oxetane, 2-methyloxetane, 2,2-dimethyloxetane, 3-methyloxetane, and 3,3-dimethyloxetane; 3-methyl -3-methoxymethyl ox etane, 3,3 -di (trifluoromethyl)perfluorooxetane, 2-chloromethyloxetane, 3,3-bis(chloromethyl)oxetane, biphenyl-type oxetane, OXT-101 (trade name, manufactured by Toagosei Co., Ltd.), and OXT-121 (trade name, manufactured by Toagosei Co., Ltd.). These oxetane resins may be used alone or in combination of two or more types thereof as appropriate.

In a case where the oxetane resin is blended, a blending amount thereof is not particularly limited, but is preferably 0.1 times to 10 times, and more preferably 0.2 times to 4 times the total amount of the maleimide resins (A) and (B) in terms of weight ratio. In a case where the blending amount of the oxetane resin is in the range of 0.1 times to 10 times, the adhesive strength and the dielectric properties of the cured object are excellent.

The carbodiimide compound that may be blended in the curable resin composition according to the present invention is not particularly limited as long as it contains at least one or more carbodiimide group in the molecule, and a generally known compound can be used.

Examples thereof include polycarbodiimides such as dicyclohexylcarbodiimide, diisopropylcarbodiimide, dimethylcarbodiimide, diisobutylcarbodiimide, dioctylcarbodiimide, t-butylisopropylcarbodiimide, diphenylcarbodiimide, di-t-butylcarbodiimide, di-β-naphthylcarbodiimide, N,N′-di-2,6-diisopropylphenylcarbodiimide, 2,6,2′,6′-tetraisopropyldiphenylcarbodiimide, cyclic carbodiimide, CARBODILITE (registered trademark: manufactured by Nisshinbo Chemical Inc.), and STABAXOL (registered trademark: manufactured by LANXESS Deutschland GmbH). These carbodiimide compounds may be used alone or in combination of two or more types thereof as appropriate.

In a case where the carbodiimide compound is blended, a blending amount thereof is not particularly limited, but is preferably 0.1 times to 10 times, and more preferably 0.2 times to 4 times the total amount of the maleimide resins (A) and (B) in terms of weight ratio. In a case where the blending amount of the carbodiimide compound is in the range of 0.1 times to 10 times, the adhesive strength and the dielectric properties of the cured object are excellent.

As the benzoxazine compound that may be blended in the curable resin composition according to the present invention, a generally known compound can be used as long as the compound has two or more dihydrobenzoxazine rings in one molecule. Examples thereof include, but are not particularly limited to, bisphenol A type benzoxazine BA-BXZ (trade name, manufactured by Konishi Chemical Co., Ltd.), bisphenol F type benzoxazine BF-BXZ (trade name, manufactured by Konishi Chemical Co., Ltd.), bisphenol S type benzoxazine BS-BXZ (trade name, manufactured by Konishi Chemical Co., Ltd.), and phenol phthalein type benzoxazine. These benzoxazine compounds may be used alone or in combination of two or more thereof as appropriate.

In a case where the benzoxazine compound is blended, a blending amount thereof is not particularly limited, but is preferably 0.1 times to 10 times, and more preferably 0.2 times to 4 times the total amount of the maleimide resins (A) and (B) in terms of weight ratio. In a case where the blending amount of the benzoxazine compound is in the range of 0.1 times to 10 times, the adhesive strength and the dielectric properties of the cured object are excellent.

The compound containing an ethylenically unsaturated group that may be blended in the curable resin composition according to the present invention is not particularly limited as long as it is a compound containing one or more ethylenically unsaturated groups in one molecule, and a generally known compound can be used. Examples thereof include compounds containing a (meth)acryloyl group and a vinyl group.

In a case where the compound containing an ethyl enically unsaturated group is blended, a blending amount thereof is not particularly limited, but is preferably 0.1 times to 10 times, and more preferably 0.2 times to 4 times the total amount of the maleimide resins (A) and (B) in terms of weight ratio. In a case where the blending amount of the compound containing an ethylenically unsaturated group is in the range of 0.1 times to 10 times, the adhesive strength and the dielectric properties of the cured object are excellent.

Examples of the compound containing a (meth)acryloyl group include methyl (meth)acrylate, ethyl (meth)acrylate, butyl (meth)acrylate, lauryl (meth)acrylate, polyethylene glycol (meth)acrylate, polyethylene glycol (meth)acrylate monomethyl ether, phenylethyl (meth)acrylate, isobornyl (meth)acrylate, cyclohexyl (meth)acrylate, benzyl (meth)acrylate, tetrahydrofurfuryl (meth)acrylate, butanediol di(meth)acrylate, hexanediol di(meth)acrylate, neopentyl glycol di(meth)acrylate, nonanediol di(meth)acryl ate, glycol di(meth)acrylate, diethylene di(meth)acrylate, polyethylene glycol di(meth)acrylate, tris(meth)acryloyloxyethyl isocyanurate, polypropylene glycol di(meth)acryl ate, adipic acid epoxy di(meth)acrylate, bisphenol ethylene oxide di(meth)acrylate, hydrogenated bisphenol ethylene oxide (meth)acrylate, bisphenol di(meth)acrylate, E-caprolactone-modified hydroxypivalic acid neopene glycol di(meth)acrylate, E-caprolactone-modified dipentaerythritol hexa (meth)acrylate, ϵ-caprolactone-modified dipentaerythritol poly(meth)acrylate, dipentaerythritol poly(meth)acrylate, trimethylolpropane tri(meth)acrylate, triethylolpropane tri(meth)acrylate, and an ethylene oxide adduct thereof; pentaerythritol tri(meth)acrylate and an ethylene oxide adduct thereof; pentaerythritol tetra(meth)acrylate, dipentaerythritol hexa(meth)acrylate, and an ethylene oxide adduct thereof.

In addition, other examples thereof include: urethane (meth)acrylates containing a (meth)acryloyl group and a urethane bond in the same molecule; polyester (meth)acrylates containing a (meth)acryloyl group and an ester bond in the same molecule; epoxy (meth)acrylates derived from an epoxy resin and containing a (meth)acryloyl group; and reactive oligomers in which these bonds are used in combination.

Examples of the urethane (meth)acrylates include reaction products of a hydroxy group-containing (meth)acrylate and polyisocyanate and, if necessary, other alcohols. Examples thereof include urethane (meth)acrylates obtained by reacting: hydroxy alkyl (meth)acrylates such as hydroxy ethyl (meth)acrylate, hydroxy propyl (meth)acrylate, and hydroxy butyl (meth)acrylate; glycerin (meth)acrylates such as glycerin mono(meth)acrylate and glycerin di(meth)acrylate;

sugar alcohol (meth)acrylates such as pentaerythritol di(meth)acrylate, pentaerythritol tri(meth)acrylate, dipentaerythritol penta(meth)acrylate, and dipentaerythritol hexa(meth)acrylate, with polyisocyanates such as toluene diisocyanate, hexamethylene diisocyanate, trimethylhexamethylene diisocyanate, isophorone diisocyanate, norbornene diisocyanate, xylene diisocyanate, hydrogenated xylene diisocyanate, dicyclohexanemethylene diisocyanate, and isocyanurates thereof and burette reaction products thereof.

Examples of the polyester (meth)acrylates include: monofunctional (poly)ester (meth)acrylates such as caprolactone-modified 2-hydroxyethyl (meth)acrylate, ethylene oxide and/or propylene oxide-modified phthalate (meth)acrylate, ethylene oxide-modified succinate (meth)acrylate, caprolactone-modified tetrahydrofurfuryl (meth)acrylate; di(poly)ester (meth)acrylates such as hydroxypivalate neopentyl glycol (meth)acrylate, caprolactone-modified hydroxypivalate neopentyl glycol (meth)acrylate, and epichlorohydrin-modified phthalate di(meth)acrylate; and mono, di, and tri(meth)acrylate of triol obtained by adding 1 mol or more of a cyclic lactone compound such as ϵ-caplolactone, γ-butyrolactone, or δ-valerolactone to 1 mol of trimethylolpropane or glycerin.

Examples thereof include mono(meth)acrylates or poly(meth)acrylates of polyhydric alcohols such as triols, tetraols, pentaols or hexaols, such as:
mono-, di-, tri- or tetra-(meth)acrylates of triols obtained by adding 1 mol or more of a cyclic lactone compound such as ϵ-caplolactone, γ-butyrolactone, or δ-valerolactone to 1 mol of pentaerythritol, dimethylolpropane, trimethylolpropane, or tetramethylolpropane; and mono- or poly(meth)acrylates of triols obtained by adding 1 mol or more of a cyclic lactone compound such as ϵ-caprolactone, γ-butyrolactone, or δ-valerolactone to 1 mol of dipentaerythritol.

Further, examples thereof include polyfunctional(poly)ester (meth)acrylates and the like such as:
(meth)acrylates of polyester polyols which are reaction products of diol components such as (poly)ethylene glycol, (poly)propylene glycol, (poly)tetramethylene glycol, (poly)butylene glycol, 3-methyl-1,5-pentanediol, and hexanediol, with polybasic acids such as maleic acid, fumaric acid, succinic acid, adipic acid, phthalic acid, isophthalic acid, hexahydrophthalic acid, tetrahydrophthalic acid, dimer acid, sebacic acid, azelaic acid, and 5-sodium sulfoisophthalic acid, and anhydrides thereof; and
(meth)acrylates of cyclic lactone-modified polyester diols containing the diol components, polybasic acids, anhydrides thereof, ϵ-caplolactone, γ-butyrolactone, and δ-valerolactone.

The epoxy (meth)acrylates are carboxylates of a compound containing an epoxy group with a (meth)acrylic acid. Examples thereof include phenol novolac-type epoxy (meth)acrylates, cresol novolac-type epoxy (meth)acrylates, trishydroxyphenylmethane-type epoxy (meth)acrylates, dicyclopentadiene phenol-type epoxy (meth)acrylates, bisphenol A-type epoxy (meth)acrylates, bisphenol F-type epoxy (meth)acrylates, biphenol-type epoxy (meth)acrylates, bisphenol A novolac-type epoxy (meth)acrylates, naphthalene skeleton-containing epoxy (meth)acrylates, glyoxal-type epoxy (meth)acrylates, heterocyclic epoxy (meth)acrylates, and acid anhydride modified epoxy acrylates thereof.

Examples of the compound containing a vinyl group include vinyl ethers such as ethyl vinyl ether, propyl vinyl ether, hydroxyethyl vinyl ether, and ethylene glycol divinyl ether. Examples of the styrenes include styrene, methylstyrene, ethylstyrene, and divinylbenzene. Other examples of the vinyl compound include triallyl isocyanurate, trimethallyl isocyanurate, and bisallylnadiimide.

These compounds containing an ethylenically unsaturated group may be used alone or in combination of two or more types thereof as appropriate.

In the curable resin composition according to the present invention, a compound containing an acid anhydride group may be further blended. As the compound containing an acid anhydride group that may be blended, a known compound can be used. Specific examples of the compound containing an acid anhydride group include a 1,2,3,4-butanetetracarboxylic dianhydride, a 1,2,3,4-cyclobutanetetracarboxylic dianhydride, a 1,2,3,4-cyclopentanetetracarboxylic dianhydride, a 1,2,4,5-cyclohexanetetracarboxylic dianhydride, a pyromellitic anhydride, a 5-(2,5-dioxotetrahydrofuryl)-3-methyl-3-cyclohexene-1,2-dicarboxylic anhydride, and a 4-(2,5-dioxotetrahydrofuran-3-yl)-1,2,3,4-tetrahydronaphthalene-1,2-dicarboxylic anhydride. The compound containing an acid anhydride group may be used alone or in combination of two or more types thereof. In addition, as a result of the reaction between the acid anhydride group and the amine, an amic acid is obtained, followed by heating at 200° C. to 300° C., an imide structure is obtained by a dehydration reaction, thereby obtaining a material having extremely excellent heat resistance.

In the curable resin composition according to the present invention, a curing accelerator (D) may be blended. Examples thereof include: imidazoles such as 2-methylimidazole, 2-ethylimidazole, 2-phenylimidazole, 2-ethyl-4-methylimidazole, 2-undecylimidazole, and 1-cyanoethyl-2-ethyl-4-methylimidazole; amines such as triethylamine, triethylene diamine, 2-(dimethylamino methyl)phenol, 1,8-diaza-bicyclo(5,4,0)-7-undecene, tris(dimethylamino methyl)phenol, and benzyldimethylamine; phosphines such as triphenylphosphine, tributylphosphine, and trioctylphosphine; organometallic salts such as tin octoate, zinc octoate, dibutyltin dimaleate, zinc naphthenate, cobalt naphthenate, and tin oleate; metal chlorides such as zinc chloride, aluminum chloride, and tin chloride; organic peroxides such as di-tert-butyl peroxide and dicumyl peroxide; azo compounds such as azobisisobutyronitrile and azobisdimethylvaleronitrile; mineral acids such as hydrochloric acid, sulfuric acid, and phosphoric acid; lewis acids such as boron trifluoride; and salts such as sodium carbonate and lithium chloride.

Specific examples of the curing accelerator (D) are shown below.

Examples of an organic peroxide-based polymerization initiator include methylethyl ketone peroxide, methyl cyclohexanone peroxide, methyl acetoacetate peroxide, acetyl acetone peroxide, 1,1-bis(t-butyl peroxy)3,3,5-trimethylcyclohexane, 1,1-bis(t-hexylperoxy)cyclohexane, 1,1-bis(t-hexylperoxy)3,3,5-trimethylcyclohexane, 1,1-bis(t-butylperoxy)cyclohexane, 2,2-bis(4,4-di-t-butylperoxycyclohexyl)propane, 1,1-bis(t-butylperoxy)cyclododecane, n-butyl 4,4-bis(t-butylperoxy)valerate, 2,2-bis(t-butylperoxy)butane, 1,1-bis(t-butylperoxy)-2-methylcyclohexane, t-butyl hydroperoxide, p-menthane hydroperoxide, 1,1,3,3-tetramethylbutyl hydroperoxide, t-hexyl hydroperoxide, dicumyl peroxide, 2,5-dimethyl-2,5-bis(t-butylperoxy)hexane, α,α′-bis(t-butylperoxy)diisopropylbenzene, t-butylcumyl peroxide, di-t-butyl peroxide, 2,5-dimethyl-2,5-bis(t-butylperoxy)hexyne-3, isobutyryl peroxide, 3,5,5-trimethylhexanoyl peroxide, octanoyl peroxide, lauroyl peroxide, cinnamic acid peroxide, m-toluoyl peroxide, benzoyl peroxide, diisopropyl peroxydicarbonate, bis(4-t-butyl cyclohexyl) peroxydicarbonate, di-3-methoxybutyl peroxydicarbonate, di-2-ethylhexyl peroxydicarbonate, di-sec-butyl peroxydicarbonate, di(3-methyl-3-methoxybutyl) peroxydicarbonate, di(4-t-butylcyclohexyl) peroxydicarbonate,α,α′-bis(neodecanoylperoxy) diisopropylbenzene, cumylperoxyneodecanoate, 1,1,3,3-tetramethylbutyl peroxyneodecanoate, 1-cyclohexyl-1-methylethyl peroxyneodecanoate, t-hexyl peroxyneodecanoate, t-butyl peroxyneodecanoate, t-hexyl peroxypivalate, t-butyl peroxypivalate, 2,5-dimethyl-2,5-bis(2-ethylhexanoylperoxy) hexane, 1,1,3,3-tetramethylbutylperoxy-2-ethylhexanoate, 1-cyclohexyl-1-methylethylperoxy-2-ethylhexanoate, t-hexylperoxy-2-ethylhexanoate, t-butylperoxy-2-ethylhexanoate, t-butyl peroxyisobutyrate, t-butyl peroxymaleic acid, t-butyl peroxylaurate, t-butyl peroxy-3,5,5-trimethylhexanoate, t-butyl peroxy isopropyl monocarbonate, t-butyl peroxy-2-ethylhexyl monocarbonate, 2,5-dimethyl-2,5-bis(benzoylperoxy)hexane, t-butyl peroxyacetate, t-hexyl peroxybenzoate, t-butylperoxy-m-toluoylbenzoate, t-butyl peroxybenzoate, bis(t-butylperoxy)isophthalate, t-butylperoxyallyl monocarbonate, and 3,3′,4,4′-tetra(t-butyl peroxycarbonyl)benzophenone.

In addition, examples of an azo-based polymerization initiator include 2-phenylazo-4-methoxy-2,4-dimethylvaleronitrile, 1-[(1-cyano-1-methylethyDazo]formamide, 1,1′-azobis(cyclohexane-1-carbonitrile), 2,2′-azobis(2-methylbutyronitrile), 2,2′-azobisisobutyronitrile, 2,2′-azobis(2,4-dimethylvaleronitrile), 2,2′-azobis(2-methylpropionamidine)dihydrochloride, 2,2′-azobis(2-methyl-N-phenylpropionamidine)dihydrochloride, 2,2′-azobis[N-(4-chlorophenyl)-2-methylpropionamidine]dihydrochloride, 2,2′-azobis [N-(4-hydrophenyl)-2-methylpropionamidine]dihydrochloride, 2,2′-azobis[2-methyl-N-(phenylmethyl)propionamidine]dihydrochloride, 2,2′-azobis[2-methyl-N-(2-propenyl)propionamidine]dihydrochloride, 2,2′-azobis[N-(2-hydroxyethyl)-2-methylpropionamidine]dihydrochloride, 2,2′-azobis[2-(5-methyl-2-imidazolin-2-yl)propane]dihydrochloride, 2,2′-azobis[2-(2-imidazolin-2-yl)propane] dihydrochloride, 2,2′-azobis[2-(4,5,6,7-tetrahydro-1H-1,3-diazepin-2-yl)propane]dihydrochloride, 2,2′-azobis[2-(3,4,5,6-tetrahydropyrimidin-2-yl)propane]dihydrochloride, 2,2′-azobis[2-(5-hydroxy-3,4,5,6-tetrahydropyrimidin-2-yl)propane]dihydrochloride, 2,2′-azobis[2-[1-(2-hydroxyethyl)-2-imidazolin-2-yl]propane]dihydrochloride, 2,2′-azobis[2-(2-imidazolin-2-y0propane], 2,2′-azobis[2-methyl-N-[1,1-bis(hydroxymethyl)-2-hydroxyethyl]propionamide], 2,2′-azobis[2-methyl-N-[1,1-bis(hydroxymethypethyl]propionamide], 2,2′-azobis[2-methyl-N-(2-hydroxyethyl)propionamide], 2,2′-azobis(2-methylpropionamide), 2,2′-azobis(2,4,4-trimethylpentane), 2,2′-azobis(2-methylpropane), dimethyl-2,2-azobis(2-methylpropionate), 4,4′-azobis(4-cyanopentanoic acid), and 2,2′-azobis[2-(hydroxymethyl)propionitrile].

Further, examples of the curing accelerator (D) include a phosphine compound, a compound containing a phosphonium salt, and an imidazole-based compound, and these may be used alone or in combination of two or more types thereof. Among them, an imidazole-based compound is preferable. Since the imidazole-based compound functions as a particularly excellent catalyst, the polymerization reaction of the maleimide resins (A) and (B) can be more reliably promoted.

The imidazole-based compound is not particularly limited, and examples thereof include 2-ethyl-4-methyl imidazole, 2-methyl imidazole, 2-ethyl imidazole, 2,4-dimethyl imidazole, 2-undecyl imidazole, 2-heptadecyl imidazole, 2-phenyl imidazole, 2-phenyl-4-methyl imidazole, 1-benzyl-2-methyl imidazole, 2-phenyl-4,5-dihydroxymethyl imidazole, 2-phenyl-4-methyl-5-hydroxy imidazole, 1-vinyl-2-methyl imidazole, 1-propyl-2-methyl imidazole, 2-isopropyl imidazole, 1-cyanoethyl-2-methyl-imidazole, 1-cyanoethyl-2-ethyl-4-methyl imidazole, 1-cyanoethyl-2-undecyl imidazole, and 1-cyanoethyl-2-phenyl imidazole. Among them, 2-methylimidazole, 2-phenylimidazole, 2-undecylimidazole, and 2-ethyl-4-methylimidazole are preferable. The use of these compounds has the advantage that the reaction of the maleimide resins (A) and (B) is further promoted and the heat resistance of the obtained cured object is improved. These may be used alone or in combination of two or more types thereof.

The phosphine compound is not particularly limited, and examples thereof include:
primary phosphines such as, alkyl phosphines such as ethylphosphine and propylphosphine, and phenylphosphine;
secondary phosphines such as, dialkyl phosphines such as dimethylphosphine and diethylphosphine, diphenylphosphine, methylphenylphosphine, and ethylphenylphosphine; and
tertiary phosphines such as, trialkyl phosphines such as trimethylphosphine, triethylphosphine, tributylphosphine, and trioctylphosphine, tricyclohexylphosphine, triphenylphosphine, alkyldiphenylphosphine, dialkylphenylphosphine, tribenzylphosphine, tritolylphosphine, tri-p-styrylphosphine, tris(2,6-dimethoxyphenyl)phosphine, tri-4-methylphenylphosphine, tri-4-methoxyphenylphosphine, and tri-2-cyanoethylphosphine. Among them, tertiary phosphines are preferably used. These may be used alone or in combination of two or more types thereof.

Examples of the compound containing a phosphonium salt include compounds containing a tetraphenylphosphonium salt, an alkyltriphenylphosphonium salt, and tetraalkylphosphonium. More specific examples thereof include tetraphenylphosphonium-thiocyanate, tetraphenylphosphonium-tetra-p-methylphenyl borate, butyltriphenylphosphonium-thiocyanate, tetraphenylphosphonium-phthalic acid, tetrabutylphosphonium-1,2-cyclohexyldicarboxylic acid, and tetrabutylphosphonium-1,2-cyclohexyldicarboxylic acid.

The curing accelerator (D) may be used alone or in combination of two or more types thereof.

A content of the curing accelerator (D) is not particularly limited, but is preferably 0.1 parts by mass to 10 parts by mass, and more preferably 0.5 parts by mass to 5 parts by mass with respect to 100 parts by mass of the total amount of a reactive resin component.

In the curable resin composition according to the present invention, for example, a photopolymerization initiator, an inorganic filler, a release agent, a flame retardant, an ion trapping agent, an antioxidant, an adhesion imparting agent, a low-stress agent, a colorant, and a coupling agent may be blended, as the component (E) other than the above components, within a range not impairing the effects of the present invention.

The curable resin composition according to the present invention may contain a photopolymerization initiator as necessary. By performing not only thermal curing but also curing by ultraviolet irradiation, the crosslinking density is further increased, and the heat resistance can be improved.

### Photopolymerization Initiator

The photopolymerization initiator according to the present invention is not particularly limited, a photopolymerization initiator used in the related art can be appropriately adopted. Examples thereof include a photopolymerization initiator such as acethophenone, 2,2-dimethoxyacetophenone, p-dimethylamino acetophenone, Michler's ketone, benzyl, benzoin, benzoin methyl ether, benzoin ethyl ether, benzoin isopropyl ether, benzoin n-propyl ether, benzoin isopropyl ether, benzoin -n-butyl ether, benzyl dimethyl ketal, thioxanthone, 2-chlorothioxanthone, 2-methylthioxanthone, 2,2-dimethoxy-1,2-diphenylethan-1-one, 1-hydroxy-cyclohexyl-phenyl-ketone, 2-hydroxy-2-methyl-1-phenyl-propan-1-one, 1-[4-(2-hydroxyethoxy)-phenyl]-2-hydroxy-2-methyl-1-propan-1-one, 2-hydroxy-1-{4-[4-(2-hydroxy-2-methyl-propionyl)-benzyl]phenyl}-2-methyl-propan-1-one, 2-methyl-1-(4 -methylthiophenyl)-2-morpholinopropan-1-one, 2-benzyl-2-dimethylamino-1-(4-morphorinophenyl)-1-butanone, 2,4,6-trimethylbenzoyl-diphenyl-phosphine oxide, bis(2,4,6-trimethylbenzoyl)-phenylphosphine oxide, 1,2-octanedione, 1-[4-(phenylthio)phenyl]-, 2-(O- benzoyloxime), ethanone, 1-[9-ethyl-6-(2-methylbenzoyl)-9H-carbazole-3-yl], 1-(O-acetyloxime), and 2,4-dimethyl thioxanthone. As such a photopolymerization initiator, these may be used alone or in combination of two or more types thereof.

Among them, as the photopolymerization initiator according to the present invention, it is preferable to use a photopolymerization initiator which efficiently generates radicals at an exposure wavelength of 310 nm to 436 nm (more preferably 365 nm) from the viewpoint that a fine pattern can be formed by using a reduction projection exposure device (stepper; light source wavelength: 365 nm, 436 nm) which is used as a standard in a manufacturing process for a protective film of a semiconductor or the like. In addition, the maleimide group to generally does not undergo homopolymerization by a radical, and a dimerization reaction of the bismaleimide compound proceeds mainly through a reaction with the radical generated from the photopolymerization initiator to form a crosslinked structure. Therefore, the present inventors presume that the bismaleimide compound is apparently less reactive than an acrylic compound or the like generally used as a photopolymerizable compound. Accordingly, from the viewpoint that radicals can be generated more efficiently and the reactivity at an exposure wavelength of 310 nm to 436 nm (more preferably 365 nm) is increased, the photopolymerization initiator according to the present invention is more preferably a compound having an oxime structure or a thioxanthone structure.

Examples of such a photopolymerization initiator include: 1,2-octanedione,1-[4-(phenylthio)phenyl]-,2-(O-benzoyloxime) (“IRGACURE OXE-01” manufactured by BASF Japan Ltd.); and ethanone,1-[9-ethyl-6-(2-methylbenzoyl)-9H-carbazole-3-yl]-,1-(O-acetyloxime) (“IRGACURE OXE-02” manufactured by BASF Japan Ltd.), which have an oxime structure, and 2,4-dimethyl thioxanthone having a thioxanthone structure (“DETX-S” manufactured by Nippon Chemical Co., Ltd.). Such a photopolymerization initiator having a high ability to generate a radical by light tends to have too high reactivity in a case of being used for photopolymerization of a general acrylic compound or the like, and is difficult to control the reaction, but can be suitably used in the present invention.

### Filler

The curable resin composition according to the present invention may further contain a filler in order to improve various properties such as coatability and heat resistance. The filler preferably has an insulating property and does not interfere with the transparency to a wavelength of 405 nm (h line). The filler is not particularly limited. Examples thereof include silica (for example, natural silica, fused silica, amorphous silica, and hollow silica), an aluminum compound (for example, boehmite, aluminium hydroxide, alumina, and aluminum nitride), a boron compound (for example, boron nitride), a magnesium compound (for example, magnesium oxide and magnesium hydroxide), a calcium compound (for example, calcium carbonate), a molybdenum compound (for example, molybdenum oxide and zinc molybdate), a barium compound (for example, barium sulfate and barium silicate), talc (for example, natural talc and calcined talc), mica, glass (for example, short fibrous glass, spherical glass, and fine powder glass (for example, E glass, T glass, and D glass)), silicone powder, fluorine resin-based filler, urethane resin-based filler, (meth)acrylic resin-based filler, polyethylene-based filler, styrene-butadiene rubber, and silicone rubber. These fillers may be used alone or in combination of two or more types thereof as appropriate.

Among them, the fillers are preferably one or more selected from the group consisting of silica, boehmite, barium sulfate, silicone powder, fluorine resin-based filler, urethane resin-based filler, (meth)acrylic resin-based filler, polyethylene-based filler, styrene-butadiene rubber, and silicone rubber.

These fillers may be surface-treated with a silane coupling agent or the like to be described later.

From the viewpoint of improving the heat resistance of the cured object obtained by curing the curable resin composition according to the present invention and obtaining good coatability, silica is preferable, and fused silica is more preferable. Specific examples of the silica include SFP-130MC manufactured by Denka Co., Ltd., and SC2050-MB, SC1050-MLE, YA010C-MFN, and YA050C-MJA manufactured by Admatechs Co., Ltd.

A particle diameter of the filler is not particularly limited, but is generally 0.005 μm to 100 μm, and preferably 0.01 μm to 50 μm.

In the curable resin composition according to the present invention, a content of the filler is not particularly limited, but is preferably 1,000 parts by mass or less, more preferably 500 parts by mass or less, and most preferably 300 parts by mass or less with respect to 100 parts by mass of the resin solid content in the curable resin composition from the viewpoint of improving the heat resistance of the cured object. In a case of containing the filler, a lower limit value is not particularly limited, but is generally 1 part by mass with respect to 100 parts by mass of the resin solid content in the curable resin composition from the viewpoint of obtaining the effect of improving various properties such as the coatability and the heat resistance.

### Silane Coupling Agent and Wetting and Dispersing Additive

In the curable resin composition according to the present invention, a silane coupling agent and/or a wetting and dispersing additive may be used in combination in order to improve the dispersibility of the filler and the adhesive strength between the polymer and/or the resin and the filler.

The silane coupling agent is not particularly limited as long as it is a silane coupling agent generally used for the surface treatment of an inorganic substance. Specific examples thereof include:
aminosilane-based agents such as 3-aminopropyltrimethoxysilane, 3-aminopropyltriethoxysilane, 3-aminopropyldimethoxymethylsilane, 3-aminopropyldiethoxymethylsilane, N-(2-aminoethyl)-3-aminopropyltrimethoxylane, N-(2-aminoethyl)-3-aminopropyltriethoxysilane, N-(2-aminoethyl)-3-aminopropyldimethoxymethylsilane, N-(2-aminoethyl)-3-aminopropyldiethoxymethylsilane, N-phenyl-3-aminopropyltrimethoxysilane, N-phenyl-3-aminopropyltriethoxysilane, [3-(6-aminohexylamino)propyl]trimethoxysilane, and [3-(N,N-dimethylamino)-propyl]trimethoxysilane;
epoxysilanes such as 3-glycidoxypropyltrimethoxysilane, 3-glycidoxypropyltriethoxysilane, 3-glycidoxypropyldimethoxy methylsilane, 3-glycidoxypropyldiethoxy methylsilane, 2-(3,4-epoxycyclohexyl)ethyltrimethoxysilane, and [8-(glycidyloxy)-n-octyl]trimethoxysilane;
vinylsilanes such as vinyltris(2-methoxyethoxy)silane, vinyltrimethoxysilane, vinyltriethoxysilane, dimethoxymethylvinylsilane, diethoxymethylvinylsilane, trimethoxy(7-octen-1-yl)silane, and trimethoxy(4-vinylphenyl)silane;
methacrylsilanes such as 3-methacryloxypropyltrimethoxysilane, 3-methacryloxypropyltriethoxysilane, 3-methacryloxypropyldimethoxymethylsilane, and 3-methacryloxypropyldiethoxymethylsilane;
acrylsilanes such as 3-acryloxypropyltrimethoxysilane and 3-acryloxypropyltriethoxysilane;
isocyanate silanes such as 3-isocyanatepropyltrimethoxysilane and 3-isocyanatepropyltriethoxysilane;
isocyanurate silanes such as tris-(trimethoxysilylpropyl)isocyanurate;
mercaptosilanes such as 3-mercaptopropyltrimethoxysilane and 3-mercaptopropyldimethoxymethylsilane;
ureidosilanes such as 3-ureidopropyltriethoxysilane;
styrylsilanes such as p-styryltrimethoxysilane;
cationic silanes such as N42-(N-vinylbenzylamino)ethyl1-3-aminopropyltrimethoxysilane hydrochloride;
acid anhydrides such as [3-(trimethoxysily0propyl]succinic anhydride; phenylsilanes such as phenyltrimethoxysilane, phenyltriethoxysilane, dimethoxymethylphenylsilane, diethoxymethylphenylsilane, and p-tolyltrimethoxysilane; and
arylsilanes such as trimethoxy(l-naphthyl)silane. These silane coupling agents may be used alone or in combination of two or more types thereof as appropriate.

In the curable resin composition according to the present invention, a content of the silane coupling agent is not particularly limited, but is generally 0.1 parts by mass to 10 parts by mass with respect to 100 parts by mass of the resin solid content in the curable resin composition. The wetting and dispersing additive is not particularly limited as long as it is a dispersion stabilizer used for a coating material. Specific examples thereof include wetting and dispersing additives such as DISPERBYK (registered trademark)-110, 111, 118, 180, and 161, BYK (registered trademark) -W996, W9010, and W903 manufactured by BYK Japan KK. These wetting and dispersing additives may be used alone or in combination of two or more types thereof as appropriate.

In the curable resin composition according to the present invention, a content of the wetting and dispersing additive is not particularly limited, but is generally 0.1 parts by mass to 10 parts by mass with respect to 100 parts by mass of the resin solid content in the curable resin composition.

### Organic Solvent

The curable resin composition according to the present invention may contain an organic solvent as necessary. In a case where an organic solvent is used, it is possible to adjust the viscosity at the time of preparing the curable resin composition. A type of the organic solvent is not particularly limited as long as it may dissolve a part or all of the resin in the curable resin composition. Specific examples thereof include, but are not particularly limited to:
ketones such as acetone, methyl ethyl ketone, and methyl isobutyl ketone;
alicyclic ketones such as cyclopentanone and cyclohexanone; cellosolve solvents such as diethylene glycol dimethyl ether, diethylene glycol diethyl ether, propylene glycol, propylene glycol monomethyl ether, propylene glycol monomethyl ether acetate, and propylene glycol monobutyl ether;
ester solvents such as ethyl lactate, methyl acetate, ethyl acetate, butyl acetate, isoamyl acetate, ethyl lactate, methyl methoxypropionate, methyl hydroxyisobutyrate, and γ-butyrolactone;
polar solvents such as amides such as dimethylacetamide and dimethylformamide; nonpolar solvents such as aromatic hydrocarbons such as toluene, xylene, and anisole;
amide-based solvents such as N-methylpyrrolidone, N,N-dimethylformamide, N,N-dimethylacetamide, and N,N-dimethyl imidazolidinone; and
sulfones such as tetramethylene sulfone.

These organic solvents may be used alone or in combination of two or more types thereof as appropriate.

### Other Components

The curable resin composition according to the present invention may use other components such as: various polymer compounds such as a thermosetting resin, a thermoplastic resin, an oligomer thereof, and an elastomer thereof, which have not been described so far; a flame retardant compound, which has not been described so far; and additives or the like, in combination in a range in which the properties of the present invention are not impaired. The other components are not particularly limited as long as it is generally used. Examples of the flame retardant compound include nitrogen-containing compounds such as melamine and benzoguanamine, phosphate compounds of phosphorus compounds, aromatic condensed phosphate esters, and halogen-containing condensed phosphate esters. Examples of the additive include an ultraviolet absorber, an antioxidant, a fluorescence brightening agent, a photosensitizer, a dye, a pigment such as phthalocyanine blue and phthalocyanine green, carbon black, a thickener, a lubricant, a defoaming agent, a surface conditioner, a brightening agent, a polymerization inhibitor, and a curing accelerator. These components may be used alone or in combination of two or more types thereof as appropriate.

In the curable resin composition according to the present invention, a content of the other components is not particularly limited, but is generally 0.1 parts by mass to 10 parts by mass with respect to 100 parts by mass of the resin solid content in the curable resin composition.

### Method For Producing Curable Resin Composition

The curable resin composition according to the present invention is prepared by appropriately mixing the components (A) to (D) and, if necessary, a resin or a compound, a photocurable initiator, a filler, other components, and an additive. The resin composition according to the present invention can be suitably used as a varnish at the time of preparing a resin sheet according to the present invention to be described below.

The method for producing the curable resin composition according to the present invention is not particularly limited, and examples thereof include a method in which the respective components described above are sequentially blended in a solvent and sufficiently stirred.

At the time of producing the curable resin composition, a known treatment (stirring, mixing, kneading, or the like) for uniformly dissolving or dispersing each component may be performed as necessary. Specifically, the dispersibility of the filler with respect to the curable resin composition can be improved by performing a stirring dispersion treatment using a stirring tank equipped with a stirrer having an appropriate stirring capacity. The stirring, mixing, and kneading can be appropriately performed using, for example, a known device such as a stirring device for dispersion such as an ultrasonic homogenizer or the like, a device for mixing such as a three-roll mill, a ball mill, a bead mill, a sand mill or the like, or a revolving or rotating mixing device. In addition, in the preparation of the curable resin composition according to the present invention, an organic solvent may be used as necessary. The type of the organic solvent is not particularly limited as long as it may dissolve the resin in the curable resin composition, and specific examples thereof are as described above.

The curable resin composition according to the present invention may be pre-polymerized. For example, a maleimide resin and a cyanate ester compound are heated in the presence or absence of a catalyst or in the presence or absence of a solvent, thereby being pre-polymerized. Similarly, the maleimide resin according to the present invention and if necessary, an epoxy resin, an amine compound, a maleimide-based compound, a cyanate ester compound, a phenolic resin, an acid anhydride compound, and other additives may be added and pre-polymerized.

### Application

The curable resin composition according to the present invention can be used for applications requiring an insulative resin composition, and is not particularly limited, but can be used for applications such as a photosensitive film, a photosensitive film with a support, a prepreg, a resin sheet, a circuit board (for application in a laminate, for application in a multilayer printed wiring board, and the like), a solder resist, an underfill material, a die bonding material, a semi-conductor sealing material, a filling resin, a component-embedding resin, and a fiber-reinforced composite material. Among them, the curable resin composition according to the present invention has excellent adhesiveness to a chip, a substrate, and the like, and is excellent in the heat resistance and the thermal stability, and thus can be suitably used for an insulating layer of a multilayer printed wiring board or for a solder resist.

### Cured Object

The cured object according to the present invention is obtained by curing the curable resin composition according to the present invention. The cured object is not particularly limited, and can be obtained by, for example, melting the curable resin composition or dissolving the curable resin composition in a solvent, then pouring the curable resin composition into a mold, and curing the curable resin composition under normal conditions using heat or light. In the case of thermal curing, the curing temperature is not particularly limited, but is preferably in the range of 120° C. to 300° C. from the viewpoint of efficiently advancing curing and preventing deterioration of the obtained cured object. In the case of photocuring, a wavelength region of light is not particularly limited, but it is preferable to perform curing in the range of 100 nm to 500 nm in which curing proceeds more efficiently with a photopolymerization initiator or the like.

### Resin Sheet

The resin sheet according to the present invention includes a support and a resin layer disposed on one surface or both surfaces of the support, and the resin layer is a resin sheet with a support containing the curable resin composition according to the present invention. The resin sheet can be produced by applying the curable resin composition onto the support and drying the curable resin composition. The resin layer in the resin sheet according to the present invention has excellent adhesiveness to a chip, a substrate, and the like, and excellent heat resistance and thermal stability.

As the support, a known support can be used, and is not particularly limited, but examples thereof include a polyimide film, a polyamide film, a polyester film, a polyethylene terephthalate (PET) film, a polybutylene terephthalate (PBT) film, a polypropylene (PP) film, a polyethylene (PE) film, a polyethylene naphthalate film, a polyvinyl alcohol film, a triacetyl acetate film, and an ethylene-tetrafluoroethylene copolymer film; a conductor foil such as a copper foil and an aluminum foil; and a glass plate, a SUS plate, and FRP.

The resin film coated with a release agent on a surface thereof can be preferably used since the release agent facilitates peeling the resin film from the resin layer. A thickness of the resin film is preferably in the range of 5 μm to 100 μm, and more preferably in the range of 10 to 50 μm. In a case where the thickness is less than 5 μm, the support tends to be easily broken at the time of being peeled off, and in a case where the thickness is more than 100 μm, the resolution at the time of exposure from above the support tends to decrease.

Further, in the resin sheet according to the present invention, the resin layer may be protected by a protective film. By protecting a resin layer side with the protective film, adhesion of dust or the like to the surface of the resin layer and scratches can be prevented. As the protective film, a film made of the same material as the resin film can be used. A thickness of the protective film is not particularly limited, but is preferably in the range of 1 to 50 μm, and more preferably in the range of 5 μm to 40 μm. In a case where the thickness is less than 1 μm, the handleability of the protective film tends to decrease, and in a case where the thickness is more than 50 μm, the protective film tends to be inferior in cost. It is preferable that the adhesive force between the resin layer and the protective film is smaller than the adhesive force between the resin layer and the support.

The method for producing a resin sheet according to the present invention is not particularly limited, and examples thereof include a method in which the curable resin composition according to the present invention is applied to a support and dried to remove the organic solvent, thereby producing a resin sheet.

The applying can be performed by a known method using, for example, a roll coater, a comma coater, a gravure coater, a die coater, a bar coater, a lip coater, a knife coater, a squeeze coater, or the like. The drying can be performed, for example, by a method of heating in a dryer at 60° C. to 200° C. for 1 minute to 60 minutes.

An amount of the organic solvent remaining in the resin layer is preferably 5% by mass or less with respect to the total mass of the resin layer from the viewpoint of preventing diffusion of the organic solvent in a subsequent step. A thickness of the resin layer is preferably 1 μm to 50 μm from the viewpoint of improving the handleability.

The resin sheet according to the present invention can be used for producing an insulating layer of a multilayer printed wiring board.

### Prepreg

In the present invention, the prepreg includes a base material and a curable resin composition impregnated or applied to the base material. A method for producing a prepreg is not particularly limited as long as it is a method for producing a prepreg by combining the curable resin composition according to the present invention and a base material. For example, the prepreg according to the present invention can be produced by impregnating or applying the curable resin composition according to the present invention to a base material, followed by semi-curing (B-stage) in a dryer at 120° C. to 220° C. for about 2 minutes to 15 minutes. At this time, the amount of the curable resin composition adhered to the base material, that is, the content of the curable resin composition (including the filler) is preferably in the range of 20 parts by mass to 99 parts by mass with respect to 100 parts by mass of the semi-cured prepreg.

As the base material used in producing the prepreg, a known substrate used in various printed wiring board materials can be used. The base material is not particularly limited, and examples thereof include: glass fibers; inorganic fibers other than glass such as quartz; organic fibers such as polyimide, polyamide, and polyester; and woven fabrics such as liquid crystal polyester. As the shape of the base material, a woven fabric, a non-woven fabric, roving, a chopped strand mat, a surfacing mat, and the like are known, and any of these may be used. The base material can be used alone or in combination of two or more types thereof. Among the woven fabrics, a woven fabric subjected to a super-opening treatment or a stuffing treatment is particularly preferable from the viewpoint of dimensional stability. A liquid crystal polyester woven fabric is preferable in view of electrical properties. The thickness of the base material is not particularly limited, but is preferably in the range of 0.01 mm to 0.2 mm in the case of a laminate application.

### Metal Foil-Clad Laminate

In the present invention, the metal foil-clad laminate includes a layer containing at least one selected from the group including the resin sheet according to the present invention and the prepreg, and a metal foil disposed on one surface or both surfaces of the layer, and the layer contains the cured object of the curable resin composition according to the present invention. In a case of using the prepreg, for example, the metal foil-clad laminate can be prepared by disposing a metal foil such as copper or aluminum on one surface or both surfaces of a prepreg or a laminate of prepregs, followed by lamination molding. The metal foil used here is not particularly limited as long as it is used for a printed wiring board material, but a copper foil such as a rolled copper foil and an electrolytic copper foil are preferable. A thickness of the metal foil is not particularly limited, but is preferably 2 μm to 70 μm, and more preferably 3 μm to 35 μm. As the molding conditions, a method used in preparation of an ordinary laminate for a printed wiring board and a multi-layer board can be adopted. For example, the metal foil-clad laminate according to the present invention can be produced by performing lamination molding using a multistage press machine, a multistage vacuum press machine, a continuous molding machine, or an autoclave molding machine under conditions of a temperature of 180° C. to 350° C., heating time of 100 minutes to 300 minutes, and a surface pressure of 20 kg/cm² to 100 kg/cm². In addition, it is also possible to prepare a multi-layer board by combining the prepreg and a wiring board for an inner layer, which is separately prepared, followed by lamination molding. In the method for producing a multi-layer board, for example, copper foils of 35 μm are disposed on both surfaces of a prepreg described above, lamination is performed under the conditions described above to form an inner layer circuit, and the circuit is blackened to form an inner layer circuit board. The inner layer circuit board and the prepreg are alternately arranged one by one, a copper foil is further arranged as the outermost layer, and the lamination molding is performed under the above-described conditions preferably under vacuum. In this way, a multi-layer board can be prepared.

The metal foil-clad laminate can be suitably used as a printed wiring board by further patterning. The printed wiring board can be manufactured according to an ordinary method, and the manufacturing method is not particularly limited. Hereinafter, an example of a method for manufacturing a printed wiring board will be described.

First, the metal foil-clad laminate is prepared. Next, the surface of the metal foil-clad laminate is subjected to an etching treatment to form an inner layer circuit, thereby preparing an inner layer substrate. The surface of the inner layer circuit of the inner layer substrate is subjected to a surface treatment for increasing the adhesive strength as necessary, and then a required number pieces of the prepreg are stacked on the surface of the inner layer circuit. Further, a metal foil for an outer layer circuit is laminated on the outer side thereof and integrally molded by heating and pressing. In this way, a multilayer laminate is produced in which the base material and the insulating layer made of the cured object of the curable resin composition are formed between the inner layer circuit and the metal foil for the outer layer circuit. Next, the multilayer laminate is subjected to a drilling process for a through hole or a via hole, and then a plating metal film for electrically connecting the inner layer circuit and the metal foil for the outer layer circuit is formed on a wall surface of the hole. Further, the metal foil for the outer layer circuit is subjected to an etching treatment to form the outer layer circuit, thereby manufacturing the printed wiring board.

The printed wiring board obtained in the manufacturing example includes an insulating layer and a conductive layer formed on one surface or both surfaces of the insulating layer, and the insulating layer contains the curable resin composition according to the present invention. For example, the prepreg according to the present invention (base material and curable resin composition according to the present invention impregnated or applied thereto) and the layer of the curable resin composition of the metal foil-clad laminate according to the present invention (layer containing curable resin composition according to the present invention) can constitute the insulating layer containing the curable resin composition according to the present invention.

### Multilayer Printed Wiring Board

In the present invention, the multilayer printed wiring board includes an insulating layer and a conductive layer formed on one surface or both surfaces of the insulating layer, and the insulating layer contains the curable resin composition according to the present invention. The insulating layer can also be obtained by, for example, stacking one or more resin sheets and curing the resin sheet. The prepreg according to the present invention may be used instead of the resin sheet according to the present invention. The multilayer printed wiring board according to the present invention can be manufactured by a conventional method, and the manufacturing method thereof is not particularly limited. Hereinafter, an example of the method for manufacturing a multilayer printed wiring board will be described.

First, the metal foil-clad laminate is prepared. Next, the surface of the metal foil-clad laminate is subjected to an etching treatment to form an inner layer circuit, thereby preparing an inner layer substrate. The surface of the inner layer circuit of the inner layer substrate is subjected to a surface treatment for increasing the adhesive strength as necessary, and then a required number pieces of the prepreg are stacked on the surface of the inner layer circuit. Further, a metal foil for an outer layer circuit is laminated on an outer side thereof and integrally molded by heating and pressing. In this way, a multilayer laminate is produced in which an insulating layer including the base material and the cured object of the curable resin composition is formed between the inner layer circuit and the metal foil for the outer layer circuit. Next, the multilayer laminate is subjected to a drilling process for a through hole or a via hole, and then a plating metal film for electrically connecting the inner layer circuit and the metal foil for the outer layer circuit is formed on a wall surface of the hole. Further, the metal foil for the outer layer circuit is subjected to an etching treatment to form the outer layer circuit, thereby producing the multilayer printed wiring board.

The printed wiring board obtained in the manufacturing example includes an insulating layer and a conductive layer formed on one surface or both surfaces of the insulating layer, and the insulating layer contains the curable resin composition according to the present invention. For example, the prepreg according to the present invention (base material and curable resin composition according to the present invention impregnated or applied thereto) and the layer of the curable resin composition of the metal foil-clad laminate according to the present invention (layer containing curable resin composition according to the present invention) can constitute the insulating layer containing the curable resin composition according to the present invention.

### Sealing Material

In the present invention, a sealing material contains the curable resin composition according to the present invention. A method for producing the sealing material is not particularly limited, and a generally known method can be appropriately applied. For example, a sealing material can be produced by mixing the curable resin composition according to the present invention with various known additives, solvents, or the like generally used for sealing material applications using a known mixer. A method of adding the maleimide compound according to the present invention, various additives, and solvents at the time of mixing is not particularly limited, and a generally known method can be appropriately applied.

### Fiber-Reinforced Composite Material

In the present invention, a fiber-reinforced composite material contains the curable resin composition according to the present invention and a reinforcing fiber. The reinforcing fiber is not particularly limited, and a generally known reinforcing fiber can be used. Examples thereof include: glass fibers such as E glass, D glass, L glass, S glass, T glass, Q glass, UN glass, NE glass, and spherical glass; carbon fibers; aramid fibers; boron fibers; PBO fibers; high-strength polyethylene fibers; alumina fibers; and silicon carbide fibers. A form and an arrangement of the reinforcing fibers are not particularly limited, and can be appropriately selected from woven fabric, unwoven fabric, mat, knit, braid, unidirectional strand, roving, chopped, and the like. In addition, it is also possible to apply a preform (fiber structures such as laminated woven base fabrics made of reinforcing fibers, or those integrated by stitching with stitch threads, a three-dimensional fabric or a braid) as the form of the reinforced fiber.

A method for producing the fiber-reinforced composite material is not particularly limited, and a generally known method can be appropriately applied. Examples thereof include a liquid composite molding method, a resin film infusion method, a filament winding method, a hand lay-up method, and a pultrusion method. Among them, the resin transfer molding method, which is one of the liquid composite molding method, is compatible to various applications since materials other than the preform, such as a metal plate, a form core, and a honeycomb core, can be set in a mold in advance. Thus, the resin transfer molding method is preferably used in a case of mass-producing composite materials having a relatively complicated shape in a short period of time.

### Adhesive

In the present invention, the adhesive contains the curable resin composition according to the present invention. A method for producing the adhesive is not particularly limited, and a generally known method can be appropriately applied. For example, the adhesive can be produced by mixing the curable resin composition according to the present invention with various known additives or solvents generally used for adhesive applications using a known mixer. A method of adding the maleimide compound according to the present invention, various additives, and solvents at the time of mixing is not particularly limited, and a generally known method can be appropriately applied.

### Semiconductor Device

In the present invention, a semiconductor device contains the curable resin composition according to the present invention. Specifically, it can be manufactured by the following method. The semiconductor device can be manufactured by mounting a semiconductor chip on a conductive portion of the multilayer printed wiring board according to the present invention. Here, the conductive portion means a portion of the multilayer printed wiring board that transmits an electric signal, and the portion may be a surface or an embedded portion. In addition, the semiconductor chip is not particularly limited as long as it is an electric circuit element made of a semiconductor.

A method for mounting the semiconductor chip at the time of manufacturing the semiconductor device is not particularly limited as long as the semiconductor chip effectively functions. Specific examples thereof include a wire bonding mounting method, a flip chip mounting method, a mounting method using a bumpless build-up layer (BBUL), a mounting method using an anisotropic conductive film (ACF), and a mounting method using a non-conductive film (NCF).

Further, a semiconductor device can also be manufactured by forming an insulating layer containing the curable resin composition according to the present invention on a semiconductor chip or a substrate on which a semiconductor chip is mounted. A shape of the substrate on which a semiconductor chip is mounted may be a wafer shape or a panel shape. After forming the insulating layer, the semiconductor device can be manufactured by the same method as that for the multilayer printed wiring board.

### EXAMPLES

Hereinafter, the present invention will be described more specifically based on examples and comparative examples, but the present invention is not limited to the following examples. Synthesis Examples 3 and 4 refer to Patent Literature 4, and Synthesis Examples 5 and 6 refer to Patent Literature 6. Expressions “parts” and “%” in the description represent “parts by weight” and “wt %”, respectively.

Gel permeation chromatography (GPC) measurement conditions according to Synthesis Examples 1 and 2 are as follows.

Model: GPC TOSOH HLC-8220GPC

Column: Super HZM-N

Eluent: THF (tetrahydrofuran); 0.35 ml/min, 40° C.

Detector: RI (differential refractometer)

Molecular weight standards: polystyrene

### Synthesis of Maleimide Resin (A)

### [Synthesis Example 1 (A-1)]

A 500 ml round-bottom flask equipped with a stirring bar coated with Teflon (registered trademark) was charged with 110 g of toluene and 36 g of N-methylpyrrolidone. Next, 85.6 g (0.16 mol) of PRIAMINE 1074 (manufactured by Croda Japan K.K.) was added, and then 15.4 g (0.16 mol) of methanesulfonic anhydride was slowly added to form a salt. Stirring and mixing were performed for about 10 minutes, and then 1,2,4,5-cyclohexane tetracarboxylic dianhydride (24.5 g, 0.08 mol) was slowly added to the stirred mixture. A Dean-Stark trap and a condenser were attached to the flask. The mixture was heated and refluxed for 6 hours to form an amine-terminated diimide. A theoretical amount of generated water from the condensation was obtained by this time. The reaction mixture was cooled to room temperature or lower, and 18.8 g (0.19 mol) of a maleic anhydride was added to the flask. The mixture was further refluxed for 8 hours to obtain an expected amount of generated water. After cooling to the room temperature, 200 ml of toluene was further added to the flask. Next, the diluted organic layer was washed with water (100 ml×3) to remove salts and unreacted raw materials. Thereafter, the solvent was removed under vacuum to obtain 108 g of amber waxy maleimide resin (A-1) (yield: 90%, Mw=3,600).

### [Synthesis Example 2 (A-2)]

A 500 ml round-bottom flask equipped with a stirring bar coated with Teflon (registered trademark) were charged with 100 g of toluene and 33 g of N-methylpyrrolidone. Next, 80.2 g (0.16 mol) of PRIAMINE 1075 (manufactured by Croda Japan K.K.) was added, and then 14.4 g (0.16 mol) of methanesulfonic anhydride was slowly added to form a salt. Stirring and mixing were performed for about 10 minutes, and then a 4-(2,5-dioxotetrahydrofuran-3-yl)-1,2,3,4-tetrahydronaphthalene-1,2-dicarboxylic anhydride (22.5 g, 0.08 mol) was slowly added to the stirred mixture. A Dean-Stark trap and a condenser were attached to the flask. The mixture was heated and refluxed for 6 hours to form an amine-terminated diimide. A theoretical amount of generated water from the condensation was obtained by this time. The reaction mixture was cooled to the room temperature or lower, and 17.6 g (0.19 mol) of a maleic anhydride was added to the flask. The mixture was further refluxed for 8 hours to obtain an expected amount of generated water. After cooling to the room temperature, 200 ml of toluene was further added to the flask. Next, the diluted organic layer was washed with water (100 ml×3 times) to remove salts and unreacted raw materials. Thereafter, the solvent was removed under vacuum to obtain 104 g of a dark amber liquid maleimide resin (A-2) (yield 93%, Mw=3,700).

Various measurement conditions according to Synthesis Examples 3 to 6 are as follows.

Softening point: measured by a method according to JIS K-7234

Acid value: measured by a method according to JIS K-0700:1992

GPC (gel permeation chromatography) analysis

Column: SHODEXGPC KF-601 (two columns), KF-602, KF-602.5, KF-603

Flow rate: 0.5 ml/min.

Column temperature: 40° C.

Solvent used: THF (tetrahydrofuran)

Detector: RI (differential refractometer)

HPLC (high-performance liquid chromatography) analysis

Column: InertsilODS-2

Flow rate: 1.0 ml/min.

Column temperature: 40° C.

Solvent used: acetonitrilewater

Detector: photodiode array (200 nm)

### [Synthesis Example3]

A flask equipped with a thermometer, a condenser, a Dean Stark azeotropic distillation trap, and a stirrer was charged with 279 parts of aniline, 100 parts of toluene, 146 parts of m-di(α-hydroxyisopropyl)benzene, and 50 parts of activated clay. The temperature in the system was increased to 170° C. over 6 hours while distilling off water and toluene, and the reaction was performed at this temperature for 13 hours. Thereafter, the mixture was cooled to the room temperature, 230 parts of toluene was added thereto, and the activated clay was removed by filtration. Next, excess aniline and toluene are distilled off from an oil layer under heating and reduced pressure using a rotary evaporator to obtain 241 parts of the aromatic amine resin (Al) represented by the above (9). The aromatic amine resin (a1) had an amine equivalent of 179 g/eq and a softening point of 46.5° C. By GPC analysis (RI), the n=l-form was 73%, and by HPLC analysis, 1,3-bis(p-aminocumyl)benzene in the n=1-form was 49%. So the content of 1,3-bis(p-aminocumyl)benzene in the aromatic amine resin was 36%.

### Synthesis Example 4 (B-1)

A flask equipped with a thermometer, a condenser, a Dean Stark azeotropic distillation trap, and a stirrer was charged with 147 parts of a maleic anhydride, 300 parts of toluene, and 4 parts of a methanesulfonic acid, followed by bringing into a heating and refluxing state. Next, a resin solution obtained by dissolving 197 parts of the aromatic amine resin (al) in 95 parts of N-methyl-2-pyrrolidone and 100 parts of toluene was added dropwise over 3 hours while maintaining the refluxing state. During this period, the condensed water and toluene, azeotroping under the refluxing condition, were cooled and separated in the Dean Stark azeotropic distillation trap, and thereafter toluene as an organic layer was returned to the system, and water was discharged out of the system. After the dropping of the resin solution was completed, the reaction was carried out for 6 hours while maintaining the refluxing state and performing the dehydration operation.

After completion of the reaction, washing with water was repeated four times to remove the methanesulfonic acid and the excess maleic anhydride, and water was removed from the system by azeotropic distillation of toluene and water under heating at 70° C. or lower and reduced pressure. Next, 2 parts of a methanesulfonic acid was added, and the reaction was carried out for 2 hours in a heating and refluxing state. After completion of the reaction, washing with water was repeated four times until the washed water became neutral, followed by removing water from the system by azeotropic distillation of toluene and water under heating at 70° C. or lower and reduced pressure, and then toluene was completely distilled off under heating and reduced pressure to obtain a maleimide resin (B-1) represented by the formula (10). The obtained maleimide resin (B-1) had a softening point of 100° C. and an acid value of 9 mgKOH/g.

### Synthesis Example 5

A flask equipped with a thermometer, a condenser, a Dean Stark azeotropic distillation trap, and a stirrer was charged with 290 parts of 2-ethylaniline, 120 parts of toluene, 117 parts of m-di(α-hydroxyisopropyl)benzene, and 24 parts of activated clay, followed by reacting at 140° C. for 8 hours and at 170° C. for 16 hours while distilling off water and toluene. Thereafter, the mixture was cooled to the room temperature, 320 parts of toluene was added thereto, and the activated clay was removed by filtration. Next, excess 2-ethylaniline and toluene are distilled off from an oil layer under heating and reduced pressure using a rotary evaporator to obtain 222 parts of an aromatic amine resin (a2) represented by the above (9). The aromatic amine resin had an amine equivalent of 201 g/eq at the room temperature. According to GPC analysis (RI), the n=1-form was 89%.

### Synthesis Example 6 (B-2)

A flask equipped with a thermometer, a condenser, a Dean Stark azeotropic distillation trap, and a stirrer was charged with 147 parts of a maleic anhydride, 300 parts of toluene, and 4 parts of a methanesulfonic acid, followed by bringing into a heating and refluxing state. Next, a resin solution obtained by dissolving 201 parts of the aromatic amine resin (a2) prepared in Synthesis Example 5 in 140 parts of toluene was added dropwise over 7 hours while maintaining a refluxing state. During this period, the condensed water and toluene, azeotroping under the refluxing condition, were cooled and separated in the Dean Stark azeotropic distillation trap, and thereafter toluene as an organic layer was returned to the system, and water was discharged out of the system. After the dropping of the resin solution was completed, the reaction was carried out for 6 hours while maintaining the refluxing state and performing the dehydration operation.

After completion of the reaction, washing with water was repeated four times to remove the methanesulfonic acid and the excess maleic anhydride, and water was removed from the system by azeotropic distillation of toluene and water under heating at 70° C. or lower and reduced pressure. Next, 2 parts of a methanesulfonic acid was added, and the reaction was carried out for 4 hours in a heating and refluxing state. After completion of the reaction, washing with water was repeated three times until the washed water became neutral, followed by removing water from the system by azeotropic distillation of toluene and water under heating at 70° C. or lower and reduced pressure, and then toluene was completely distilled off under heating and reduced pressure to obtain a maleimide resin (B-2) represented by the formula (10). The obtained maleimide resin (B-2) had a softening point of 93° C. and an acid value of 9 mgKOH/g. According to GPC analysis (RI), the n=1-form was 87%.

### Synthesis Example 7 (C-2)

A flask equipped with a thermometer, a condenser, and a stirrer were charged with 225 g of XD-1000 (manufactured by Nippon Kayaku Co., Ltd., softening point: 74.8° C., epoxy equivalent: 255 g/eq.), 72.1 g of an acrylic acid, 3 g of triphenylphosphine as a catalyst, and propylene glycol monomethyl ether monoacetate as a solvent so that the solid content is 80%, followed by carrying out the reaction at 100° C. for 24 hours to obtain an epoxy carboxylate compound solution as a reaction intermediate.

Subsequently, 140 g of a 1,2,3,6-tetrahydrophthalic anhydride (THPA) (trade name: RIKACID TH, manufactured by New Japan Chemical Co., Ltd.) was added as a polybasic acid anhydride to the obtained reactive epoxy carboxylate compound solution, and propylene glycol monomethyl ether monoacetate was added as a solvent so that the solid content was 65%, followed by carrying out the reaction at 100° C. for 6 hours to obtain a reactive polycarboxylic acid compound (C-2). The solid acid value (AV: mgKOH/g) of the obtained reactive polycarboxylic acid compound (C-2) was 110.

### Examples 1 to 5

### Preparation of Curable Resin Composition and Resin Film

The following components were blended in the compositions shown in Table 1 to prepare curable resin compositions according to Examples 1 to 5. The curable resin composition was applied, using an applicator, onto an ultra-low roughness electrolytic copper foil (CF-T4X-SV (trade name), manufactured by Fukuda Metal Foil & Powder Co., Ltd.) of 12 μm on a hot plate heated to 60° C., and subjected to a heat treatment at 120° C. for 30 minutes using an oven to prepare a resin film having a thickness of 100 μm in a B-stage state.

Thereafter, the ultra-low roughness electrolytic copper foil (CF-T4X-SV (trade name), manufactured by Fukuda Metal Foil & Powder Co., Ltd.) of 12 p.m was bonded to the obtained resin film in a B-stage state using a laminator, followed by heating at 220° C. for 2 hours to complete thermal curing.

In Example 4, the ultra-low roughness electrolytic copper foil (CF-T4X-SV (trade name), manufactured by Fukuda Metal Foil & Powder Co., Ltd.) of 12 μm was bonded to, using a laminator, the resin film in a B-stage state after exposure to light at 100 mJ/cm² (irradiation intensity: 10 mW/cm², 10 seconds) using an ultra-high pressure mercury lamp (USH-500BY1, manufactured by Ushio Corporation), followed by heating at 220° C. for 2 hours to complete thermal curing.

<(A) Maleimide Resin>

(A-1) Maleimide Resin Represented by Formula (2)

Maleimide resin (A-1) according to Synthesis Example 1 (compound represented by the following formula (20), high-viscous liquid at 25° C.)

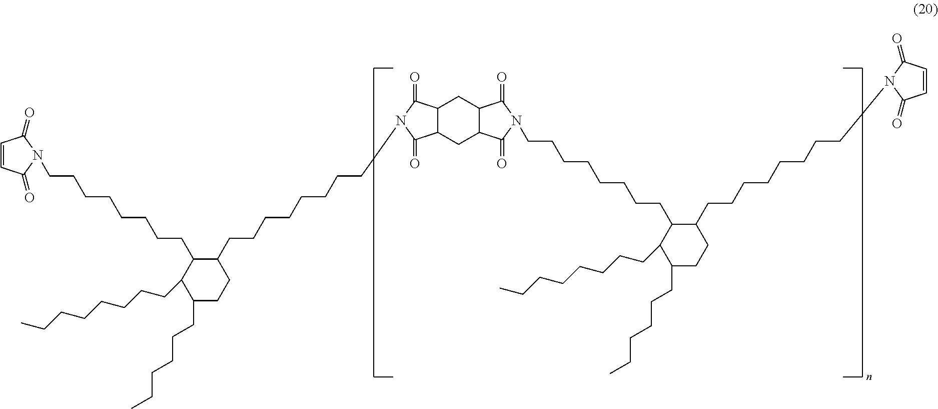

(A-2) Maleimide Resin Represented by Formula (2)

Maleimide resin (A-2) according to Synthesis Example 2 (compound represented by the following formula (21), high-viscous liquid at 25° C.)

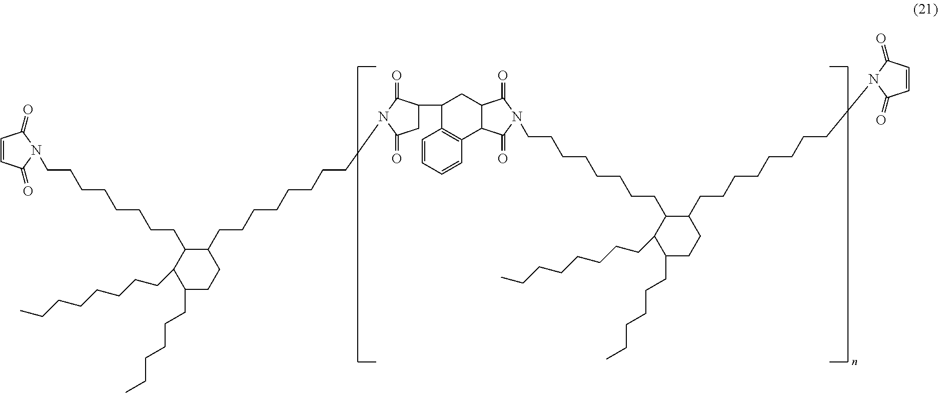

<(B) Maleimide Resin>
(B-1) Maleimide resin represented by the formula (10). (R in the formula (10) is a hydrogen atom)

Maleimide resin (B-1) according to Synthesis Example 4
(B-2) Maleimide resin represented by the formula (10). (R in the formula (10) is an ethyl group)

Maleimide resin (B-2) according to Synthesis Example 6

<(C) Thermosetting Resin>
(C-1) BMI-689 (compound represented by the following formula (22), manufactured by DESIGENER MOLECURES Inc., liquid at 25° C.)

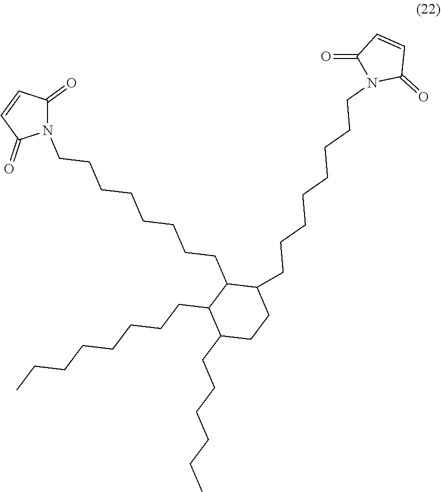 [SMILES: CCCCCCCCC1C(CCCCCC)CCC(CCCCCCCCN2C(=O)C=CC2=O)C1CCCCCCCCN1C(=O)C=CC1=O]

(C-2) Compound Represented by Formula (23)

Compound (C-2) according to Synthesis Example 7

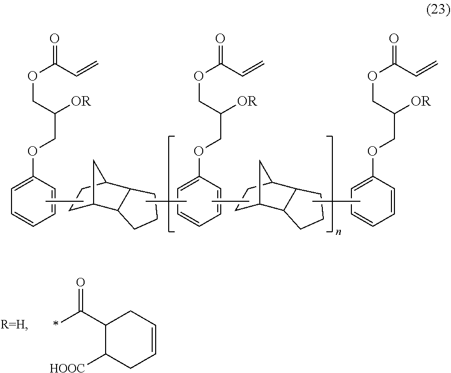

<(D) Curing Accelerator>
(D-1) Percumyl D (dicumyl peroxide, manufactured by NOF Corporation)
(D-2) 2-ethyl-4-methylimidazole (manufactured by Shikoku Chemicals Corporation)

<(E) Photopolymerization Initiator>
(E-1) Ethanone, 1-[9-ethyl-6-(2-methylbenzoyl)-9H-carbazol-3-yl]-, 1-(O-acetyloxime)

(“IRGACURE OXE-02” manufactured by BASF Japan Ltd.)

<Preparation of Copper Foil Laminate>

The resin film peeled off by etching and two copper foils (CF-T4X-SV (trade name), manufactured by Fukuda Metal Foil & Powder Co., Ltd.) were laminated so that mirror surfaces of the copper foils faced the resin film, followed by thermocompression bonding by hot pressing under conditions of 220° C., 1.0 MPa, and 2 hours to obtain a copper foil laminate in which the copper foil, a cured object of the resin film, and the copper foil were laminated in this order.

<Properties Evaluation>

The following various properties were measured for the curable resin compositions and the copper foil laminate thus produced. The results are shown in Table 1.

[Compatibility]

The visual compatibility refers to a state of visual observation of the curable resin composition after blending and stirring the components (A) to (D). A case where the compatibility is good indicates that there is no precipitate or the like and application to the base material or the like is possible, and a case where the compatibility is poor indicates that there is a precipitate or the like and application to the base material or the like becomes difficult.
(Evaluation Standard)

A: Precipitate absent

B: Precipitate present

[Haze Value]

The curable resin composition was put into a square cell having an optical path length of 10 mm, and the curable resin composition was irradiated with light under a condition of 25° C. using a simultaneous measurement instrument for color and turbidity (COH 400, manufactured by Nippon Denshoku Industries Co., Ltd), thereby determining the haze by the following calculation formula (1) using a ratio of a diffused light transmittance (Td) of transmitted light diffused by a sheet to a total light transmittance (Tt) representing a total amount of transmitted light in accordance with JIS K7136. The total light transmittance (Tt) is a sum of the diffused light transmittance (Td) and a parallel light transmittance (Tp) transmitted coaxially with the incident light.

Haze (H)=Td/Tt x 100(1)

The haze of the curable resin composition thus obtained was evaluated in four stages.

AA: Haze is less than 30

A: Haze is 30 or more and less than 50

B: Haze is 50 or more and less than 70

C: Haze is 70 or more

10 [Dielectric Properties]

The copper foils on both surfaces of the copper foil laminate were removed by etching, followed by drying at 130° C. for 30 minutes, and then the cured object of the resin film was cut to prepare a test piece of 10 cm×5 cm. With respect to the obtained test piece, a relative permittivity and a loss tangent at 10 GHz were measured with a cavity resonator method permittivity measuring apparatus (manufactured by AET, Inc.). After the measurement, the test piece was immersed in water for 24 hours to absorb water, then taken out from the water, wiped off the water, and left to stand in an environment of 25° C. and 20% for one day, and then the relative permittivity and the loss tangent at 10 GHz were measured again.

[Tensile Elastic Modulus]

The copper foils on both surfaces of the copper foil laminate were removed by etching, followed by drying at 130° C. for 30 minutes, and then the cured object of the resin film was cut to prepare a test piece of 6 cm×5 mm. With respect to the obtained test piece, the tensile elastic modulus and the elongation were measured at 25° C. and a speed of 5 mm/min using a tensile tester (trade name “RTG-1201”, manufactured by A&D Corporation).

[Heat Resistance]

The copper foils on both surfaces of the copper foil laminate were removed by etching, followed by drying at 130° C. for 30 minutes, thereafter the cured object of the resin film was cut into a 4 mm square, 1.0 mg to 5.0 mg was measured in a measuring pan, and the 5% weight loss rate (Td5) was measured at an air flow rate of 100 mL/sec and a temperature increase rate of 10° C./min. As the measurement device, TGA/DSC1 (manufactured by METTLER TOLEDO) was used.

[Glass Transition Temperature]

The copper foils on both surfaces of the copper foil laminate were removed by etching, followed by drying at 130° C. for 30 minutes, and then the cured object of the resin film was cut to prepare a test piece of 5 cm×5 mm. With respect to the obtained test piece, a temperature measured by a dynamic viscoelastic tester (DMA: trade name “RSA-G2”, manufactured by TA Instruments) when tans was the maximum value was determined as the glass transition temperature. Further, a tans peak waveform was verified from the viewpoint of compatibility, and the number of peaks was counted.

[Water Absorption Rate]

The copper foils on both surfaces of the copper foil laminate were removed by etching, followed by drying at 130° C. for 30 minutes, and then the cured object of the resin film was cut to prepare a test piece of 10 cm×5 cm. The obtained test piece was immersed in water for 24 hours to absorb water and then taken out from the water to wipe off water, and thereafter, a weight increase rate of the test piece was defined as the water absorption rate.

[HAST Resistance]

The curable resin composition was applied onto Espanex M series (base imide manufactured by Nippon Steel Chemical Co., Ltd., thickness of 25 μm, Cu thickness of 18 μm) on which a comb-like pattern of L/S=100 μm/100 p.m was formed by a screen printing method so as to have a thickness of 25 μm, and the applied film was dried by a hot air dryer at 120° C. for 60 minutes. Next, a resin surface was covered with Aflex (Grade: 25N NT) (manufactured by AGC Corporation) and heated at 220° C. for 2 hours to obtain a test substrate for HAST evaluation. An electrode portion of the obtained substrate was subjected to wiring connection by a solder, and placed in an environment of 130° C. and 85% RH, followed by applying a voltage of 100 V, and the time was measured until the resistance value became 1×10⁸ Ω or less.

In Example 4, after the solvent was dried, exposure to light at 100 mJ/cm² (irradiation intensity: 10 mW/cm², 10 seconds) using an ultra-high pressure mercury lamp (USH-500BY1, manufactured by USHIO INC.) is performed, and then Aflex (Grade: 25N NT, manufactured by AGC Corporation) is bonded using a laminator, followed by heating at 220° C. for 2 hours to complete thermal curing.

A: 100 hours or longer

B: longer than 20 hours and shorter than 100 hours

C: 20 hours or shorter

TABLE 1

| | | Examples | | | | |
|---|---|---|---|---|---|---|
| Component | Materials | 1 | 2 | 3 | 4 | 5 |
| Maleimide | A-1 | 88 | | 57 | 46 | 46 |
| resin (A) | A-2 | | 80 | | | |
| Maleimide | B-1 | 10 | 20 | 40 | 8 | |
| resin (B) | B-2 | | | | | 8 |
| Thermosetting | C-1 | 2 | | 3 | | |
| resin (C) | C-2 | | | | 42 | 42 |
| Curing | D-1 | 1 | 1 | | 1 | 1 |
| accelerator (D) | D-2 | | | 1 | | |
| Photopolymerization | OXE-02 | | | | 0.5 | 0.5 |
| initiator (E) | | | | | | |
| Solvent | Toluene | 30 | 30 | 30 | | |
| | Propylene glycol | | | | 34 | 34 |
| | monomethyl ether | | | | | |
| | monoacetate | | | | | |
| Total | | 131 | 131 | 131 | 131.5 | 131.5 |
| Liquid | Visual Compatibility | A | A | A | A | A |
| compatibility | Haze value | AA | AA | AA | AA | AA |
| Dielectric | Permittivity Dk | 2.3 | 2.3 | 2.4 | 2.7 | 2.6 |
| property | Loss tangent Df | 0.0013 | 0.0013 | 0.0015 | 0.0068 | 0.0071 |
| | Permittivity Dk after | 2.3 | 2.4 | 2.5 | 2.5 | 2.7 |
| | absorbing water | | | | | |
| | Loss tangent Df after | 0.0014 | 0.0014 | 0.0019 | 0.0073 | 0.0075 |
| | absorbing water | | | | | |
| Mechanical | Tensile elastic | 132 | 189 | 420 | 284 | 274 |
| property | modulus (Mpa) | | | | | |
| | Elongation at break (%) | 120 | 113 | 84 | 115 | 100 |
| Adhesive strength | 90° peel (kN/m) | 1 | 1.2 | 1.2 | 0.9 | 0.9 |
| Thermal | Tg (° C.) | 63 | 70 | 95 | 134 | 130 |
| property | | 1 peak | 1 peak | 1 peak | 1 peak | 1 peak |
| | 5% weight loss | 401 | 405 | 420 | 389 | 388 |
| | rate (Td5) | | | | | |
| | Solder resistance | A | A | A | A | A |
| Insulation | Water absorption | 0.02 | 0.03 | 0.04 | 0.11 | 0.11 |
| reliability | ratio(%) | | | | | |
| | HAST resistance | A | A | A | A | A |

As is clear from the results shown in Table 1, it is confirmed that the curable resin compositions according to Examples 1 to 5 have good adhesiveness to the base material and have low dielectric properties, low elastic modulus, high heat resistance, and low water absorption as the properties of the cured object. Therefore, the curable resin composition according to the present invention can be used for applications such as a photosensitive film, a photosensitive film with a support, a prepreg, a resin sheet, a circuit board (application for a laminate, application for a multilayer printed wiring board, and the like), a solder resist, an underfill material, a die bonding material, a semi-conductor sealing material, a filling resin, a component-embedding resin, and a fiber-reinforced composite material. Accordingly, it is possible to dramatically improve the properties of a laminate such as a printed substrate and an electronic component such as a semiconductor device.

Although the present invention has been described in detail with reference to specific embodiments, it is apparent to those skilled in the art that various changes and modifications can be made without departing from the spirit and scope of the present invention.

This application is based on a Japanese patent application (Japanese Patent Application No. 2021-056835) filed on Mar. 30, 2021, the entirety of which is incorporated by reference. In addition, all references cited herein are incorporated in entirety thereof.

1. A curable resin composition comprising:
a maleimide resin (A) having a cyclic imide bond obtained by reacting a diamine (a-1) derived from a dimer acid, a tetracarboxylic dianhydride (a-2), and a maleic anhydride;
a maleimide resin (B) represented by the following formula (1); and
a curing accelerator (D), wherein
the components (A), (B), and (D) are compatible with one another, 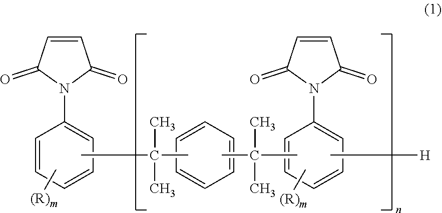
in the formula (1), plural R each independently represent a hydrogen atom or an alkyl group having 1 to 5 carbon atoms. m represents an integer of 0 to 3. n represents the number of repetitions, and an average value thereof is 1<n<5.

2. The curable resin composition according to claim 1, wherein
the component (A) is represented by the following formula (2): 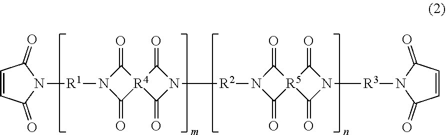
in the formula (2),
R¹ represents a divalent hydrocarbon group (a) derived from a dimer acid,
R² represents a divalent organic group (b) other than the divalent hydrocarbon group (a) derived from a dimer acid,
R³ represents any one selected from the group consisting of:
the divalent hydrocarbon group (a) derived from a dimer acid; and
the divalent organic group (b) other than the divalent hydrocarbon group (a) derived from a dimer acid, and
R⁴ and R⁵ each independently contain one or more organic groups selected from:
a tetravalent organic group having 6 to 40 carbon atoms and having a monocyclic or condensed polycyclic alicyclic structure,
a tetravalent organic group having 4 to 40 carbon atoms in which organic groups having a monocyclic alicyclic structure are linked to one another directly or via a crosslinked structure; and
a tetravalent organic group having 4 to 40 carbon atoms and having a semi-alicyclic structure including both an alicyclic structure and an aromatic ring,
in an amount of 5 mol % to 95 mol % when a total amount of R⁴ and R⁵ is 100 mol %, m is an integer of 1 to 30,
n is an integer of 0 to 30, in a case where m is 2 or more, plural R¹ and R⁴ may be the same or different, and in a case where n is 2 or more, plural R² and R⁵ may be the same or different.

3. The curable resin composition according to claim 1, wherein
the component (a-2) is represented by the following formula (3-a): 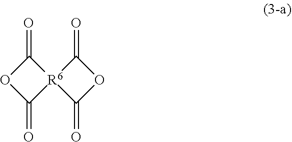
in the formula (3-a), R⁶ represents a tetravalent organic group having 4 to 40 carbon atoms including a hydrocarbon ring, and the organic group may contain an aromatic ring.

4. The curable resin composition according to claim 3, wherein
the component (a-2) is selected from the group consisting of the following formulae (4-1a) to (4-11a): 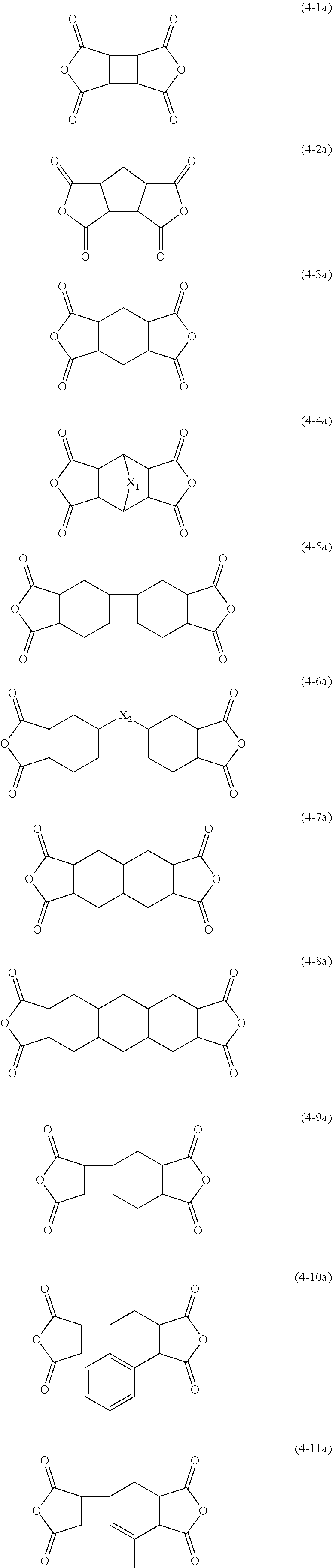
in the formula (4-4a), X₁ represents a direct bond, an oxygen atom, a sulfur atom, a sulfonyl group, or a divalent organic group having 1 to 3 carbon atoms. In the formula (4-6a), X₂ represents a direct bond, an oxygen atom, a sulfur atom, a sulfonyl group, or a divalent organic group having 1 to 3 carbon atoms or arylene group.

5. The curable resin composition according to claim 1, further comprising:
a thermosetting resin (C) other than the component (A) and the component (B), wherein
the components (A) to (D) are compatible with one another.

6. The curable resin composition according to claim 5, wherein
the component (C) is one or more selected from the group consisting of: a maleimide compound other than the component (A) and the component (B), a cyanate ester compound, a phenolic resin, an epoxy resin, an oxetane resin, a benzoxazine compound, a carbodiimide compound, and a compound containing an ethylenically unsaturated group.

7. The curable resin composition according to claim 5, wherein
the component (C) is a compound represented by the following formula (5): 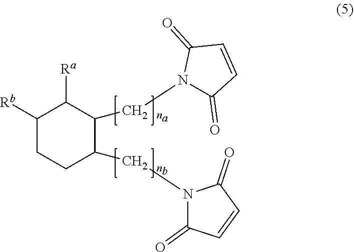
in the formula (5), R^{a} and R^{b} each independently represents a linear or branched alkyl group having 1 to 16 carbon atoms, or a linear or branched alkenyl group having 1 to 16 carbon atoms. na represents the number of 1 to 16, and nb represents the number of 1 to 16. na and nb may be the same or different.

8. The curable resin composition according to claim 1, wherein
the component (a-2) is a compound represented by the following formula (6):

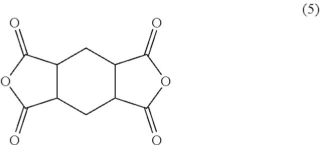 [SMILES: O=C1OC(=O)C2CC3C(=O)OC(=O)C3CC12]

9. The curable resin composition according to claim 1, wherein
the component (a-2) is a compound represented by the following formula (7)

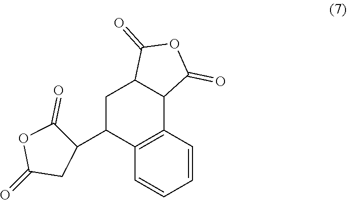 [SMILES: O=C1CC(C2CC3C(=O)OC(=O)C3c3ccccc32)C(=O)O1]

10. The curable resin composition according to claim 1, wherein
the component (D) contains at least one selected from a thermal radical polymerization initiator and an imidazole compound.

11. The curable resin composition according to claim 10, wherein
the thermal radical polymerization initiator is an organic peroxide.

12. The curable resin composition according to claim 1, wherein
a content of the component (A) is 30 wt % or more and less than 95 wt %, and a content of the component (B) is 3 wt % or more and less than 60 wt % in a total amount of the curable resin composition, and
the content of the component (A) is larger than the content of the component (B).

13. The curable resin composition according to claim 1, having a haze value of less than 50 that is measured at an optical path length of 10 mm in accordance with JIS K7136.

14. A resin sheet comprising the curable resin composition according to claim 1.

15. A cured object obtained by curing the curable resin composition according to claim 1.

16. A semiconductor device and a semiconductor substrate comprising the cured object according to claim 15 as at least one selected from the group consisting of a surface protective film, an interlayer insulating film, an insulating film of a redistribution layer, and an underfill.
